(19) United States
(12) Patent Application Publication
(10) Pub. No.: US 2017/0052295 A1
(43) Pub. Date: Feb. 23, 2017

(54) OPTICAL MEMBER, PRODUCTION METHOD THEREFOR, WINDOW MATERIAL, AND FIXTURE

(71) Applicant: DEXERIALS CORPORATION, Tokyo (JP)

(72) Inventors: Ryoko Sakuma, Tokyo (JP); Masayuki Tanishima, Tokyo (JP); Tsutomu Nagahama, Tokyo (JP)

(21) Appl. No.: 15/306,372

(22) PCT Filed: Feb. 16, 2015
(86) PCT No.: PCT/JP2015/054121

§ 371 Date: Oct. 24, 2016

(30) Foreign Application Priority Data
Apr. 24, 2014 (JP) 2014-090242

(51) Int. Cl. G02B 5/20; E06B 9/24; B05D 1/02; G02B 5/26; C23C 16/44; B05D 1/18

(52) U.S. Cl. CPC G02B 5/208; C23C 16/44; B05D 1/18; B05D 1/02; G02B 5/26; E06B 9/24; E06B 2009/2417

(57) ABSTRACT

An optical member including a first optical layer having convex shapes, and a reflective layer, which is formed on the convex shapes of the first optical layer and is configured to reflect light including at least infrared light, wherein the reflective layer includes at least a metal layer, wherein a maximum height roughness Rz (nm) of inclined planes of the convex shapes is 3.0 times or less an average thickness (nm) of the metal layer, and wherein the average thickness of the metal layer is 40 nm or less.

### TECHNICAL FIELD

The present invention relates to an optical member and a production method of the optical member, and a window material and joinery.

### BACKGROUND ART

Recently, window films for shielding sunlight have been widely used for the purpose of reducing loads of air conditioning (see, for example, PTL 1). As window films for shielding sunlight, there are films that absorb sunlight and films that reflect sunlight.

Regarding the films that reflect sunlight, techniques using an optical multi-layer film, a metal-containing film, or a transparent conductive film is used as a reflective layer have been already known (see, for example, PTL 2 to PTL 5). However, the reflective layer can only regular-reflect incident sunlight, because the reflective layer is typically disposed on planar glass. Therefore, the light emitted from the sky and regular-reflected by the reflective layer reaches another building outside or ground, and absorbed by the building or the ground to transformed into heat to increase a temperature of the surroundings. As a result, a local increase in the temperature is caused in the surrounding area of buildings having windows, to entire areas of which the above-described reflective layers are bonded. In the city, therefore, the heat island effect is accelerated, and problems are caused, such as lawns do not grow only in the area where reflected light is applied.

In order to prevent the acceleration of the heat island effect due to the regular reflection, techniques for directionally reflect sunlight in the directions other than regular reflection have been proposed. As a method for improving reflection to the sky, for example, a reflection structure of a grooved surface using an optical refractive index film has been proposed (see, for example, PTL 6 to PTL 8).

However, the above-mentioned window films have a problem that durability of the films is insufficient due to the complicated structures.

### CITATION LIST

### Patent Literature

PTL 1 International Publication No. WO 05/087680

PTL 2 Japanese Patent Application Laid-Open (JP-A) No. 04-357025

PTL 3 JP-A No. 07-315874

PTL 4 JP-A No. 2012-47812

PTL 5 JP-A No. 2008-180770

PTL 6 JP-A No. 2010-160467

PTL 7 JP-A No. 2012-3024

PTL 8 JP-A No. 2011-175249

### SUMMARY OF INVENTION

### Technical Problem

The present invention aims to solve the above-described various problems in the conventional art, and achieve the following object. Specifically, the present invention has an object to provide an optical member having excellent durability with a complex structure, and a production method of the optical member, as well as a window material and joinery both containing the optical member.

### Solution to Problem

The means for solving the above-described problems are as follows.

<1> An optical member including:

a first optical layer having convex shapes; and

a reflective layer, which is formed on the convex shapes of the first optical layer and is configured to reflect light including at least infrared light,

wherein the reflective layer includes at least a metal layer,

wherein a maximum height roughness Rz (nm) of inclined planes of the convex shapes is 3.0 times or less an average thickness (nm) of the metal layer, and

wherein the average thickness of the metal layer is 40 nm or less.

<2> The optical member according to <1>,

wherein the convex shapes of the first optical layer are formed with a one-dimensional alignment or a two-dimensional alignment of a plurality of structures, and the structures are prism shapes, lenticular shapes, hemispherical shapes, or corner cube shapes.

<3> The optical member according to <1> or <2>,

wherein the first optical layer is formed of a thermoplastic resin, an active energy ray-curable resin, or a thermosetting resin.

<4> The optical member according to any one of <1> to <3>,

wherein each of the convex shapes of the first optical layer is a shape including a plane inclined at 45° or greater relative to a plane of the first optical layer opposite to the plane on which the convex shapes are formed.

<5> The optical member according to any one of <1> to <4>,

wherein a pitch of the convex shapes of the first optical layer is from 20 μm to 150

<6> A window material including:

the optical member according to any one of <1> to <5>.

<7> Joinery including:

a light collection part from which sunlight is taken in,

wherein the light collection part includes the optical member according to any one of <1> to <5>.

<8> A production method of the optical member according to any one of <1> to <5>, the production method including:

forming the first optical layer having convex shapes using a transfer master having concave shapes; and

forming the reflective layer on the convex shapes of the first optical layer, where the reflective layer includes at least a metal layer and is configured to reflect light including at least infrared light.

### Advantageous Effects of the Invention

The present invention can solve the above-described various problems in the conventional art, achieve the above-mentioned object, and provide an optical member having excellent durability with a complex structure, and a production method of the optical member, as well as a window material and joinery both containing the optical member.

### BRIEF DESCRIPTION OF DRAWINGS

FIG. 1A is a perspective view illustrating an example of shapes of structures formed in a first optical layer.

FIG. 1B is a cross-sectional view illustrating a direction of inclination of a main axis of the structure formed in the first optical layer.

FIG. 2A is a perspective view illustrating an example of shapes of structures formed in a first optical layer.

FIG. 2B is a perspective view illustrating an example of shapes of structures formed in a first optical layer.

FIG. 2C is a perspective view illustrating an example of shapes of structures formed in a first optical layer.

FIG. 3 is a cross-sectional view illustrating one example of a function of an optical member.

FIG. 4 is a cross-sectional view illustrating one example of a function of an optical member.

FIG. 5 is a cross-sectional view illustrating one example of a function of an optical member.

FIG. 6 is a cross-sectional view illustrating one example of a function of an optical member.

FIG. 7A is a cross-sectional view illustrating a relationship between the ridge line of the pillar-shaped structure, incident light, and reflected light.

FIG. 7B is a cross-sectional view illustrating a relationship between the ridge line of the pillar-shaped structure, incident light, and reflected light.

FIG. 8 is a perspective view illustrating a relationship between incident light entering an optical member and reflected light reflected by the optical member.

FIG. 9 is a schematic diagram for explaining a reflection function of the optical member bonded to a window material.

FIG. 10 is a perspective view illustrating one structural example of the joinery of the present invention.

FIG. 11A is a process diagram for explaining one example of the production method of an optical member of the present invention.

FIG. 11B is a process diagram for explaining one example of the production method of an optical member of the present invention.

FIG. 11C is a process diagram for explaining one example of the production method of an optical member of the present invention.

FIG. 11D is a process diagram for explaining one example of the production method of an optical member of the present invention.

FIG. 11E is a process diagram for explaining one example of the production method of an optical member of the present invention.

FIG. 11F is a process diagram for explaining one example of the production method of an optical member of the present invention.

FIG. 12 is a schematic view illustrating one structural example of a production device for the optical member of the present invention.

FIG. 13 is a schematic view illustrating one structural example of a production device for the optical member of the present invention.

FIG. 14 is a cross-sectional view illustrating one structural example of the optical member according to the first embodiment of the present invention.

FIG. 15A is a plan view illustrating one structural example of structures of the optical member according to the second embodiment of the present invention.

FIG. 15B is a cross-sectional view cut the optical member of FIG. 15A along the line B-B.

FIG. 15C is a cross-sectional view cut the optical member of FIG. 15A along the line C-C.

FIG. 16A is a plan view illustrating one structural example of structures of the optical member according to the second embodiment of the present invention.

FIG. 16B is a cross-sectional view cut the optical member of FIG. 16A along the line B-B.

FIG. 16C is a cross-sectional view cut the optical member of FIG. 16A along the line C-C.

FIG. 17A is a plan view illustrating one structural example of structures of the optical member according to the second embodiment of the present invention.

FIG. 17B is a cross-sectional view cut the optical member of FIG. 17A along the line B-B.

FIG. 18 is a cross-sectional view illustrating one structural example of the optical member according to the third embodiment of the present invention.

FIG. 19 is a cross-sectional view illustrating one structural example of the optical member according to the fourth embodiment of the present invention.

FIG. 20 is a perspective view illustrating one structural example of structures of the optical member according to the fourth embodiment of the present invention.

FIG. 21 is a cross-sectional view illustrating one structural example of the optical member according to the fifth embodiment of the present invention.

FIG. 22A is a cross-sectional view illustrating one structural example of the optical member according to the sixth embodiment of the present invention.

FIG. 22B is a cross-sectional view illustrating one structural example of the optical member according to the sixth embodiment of the present invention.

FIG. 22C is a cross-sectional view illustrating one structural example of the optical member according to the sixth embodiment of the present invention.

FIG. 23 is a cross-sectional view illustrating one structural example of the optical member according to the seventh embodiment of the present invention.

FIG. 24A is a cross-sectional view illustrating one structural example of the optical member according to the eighth embodiment of the present invention.

FIG. 24B is a cross-sectional view illustrating one structural example of the optical member according to the eighth embodiment of the present invention.

FIG. 25 is a cross-sectional view illustrating one structural example of the optical member according to the ninth embodiment of the present invention.

FIG. 26 is a cross-sectional view illustrating one structural example of the optical member according to the ninth embodiment of the present invention.

FIG. 27 is a cross-sectional view illustrating one structural example of the optical member according to the tenth embodiment of the present invention.

FIG. 28 is a cross-sectional view illustrating one structural example of the optical member according to the eleventh embodiment of the present invention.

FIG. 29A is a cross-sectional view illustrating a shape of a molding surface of the nickel-phosphorous plated SUS mold of Example 1.

FIG. 29B is a cross-sectional view illustrating a shape of a molding surface of the nickel-phosphorous plated SUS mold of Example 1.

### DESCRIPTION OF EMBODIMENTS

### Optical Member

An optical member of the present invention includes a first optical layer and a reflective layer, and may further include other layers according to the necessity.

<First Optical Layer>

The first optical layer has convex shapes and is transparent to visible light.

In the present specification, the convex shapes means a shape where protrusions are continuously or discontinuously formed. The shape where protrusions are continuously or discontinuously formed can be, in other words, a shape where recesses are continuously or discontinuously formed. The shape where recesses are continuously or discontinuously formed is also referred to as recess shapes. Accordingly, in the present invention, convex shapes are the same as recess shapes.

Examples of a material of the first optical layer include resins, such as thermoplastic resins, active energy ray-curable resins, and thermosetting resins.

The first optical layer is not particularly limited and may be appropriately selected depending on the intended purpose, as long as the first optical layer is a support for supporting the reflective layer.

Each convex shape is preferably a shape including a plane inclined at 45° or greater relative to a plane of the first optical layer opposite to the plane on which the convex shapes are formed. Since the convex shapes are the above-described shapes, incident light is returned back to the sky with substantially one reflection, the incident light can be effectively reflected to the direction of the sky with the reflective layer a reflectance of which is not very high, and absorption of light by the reflective layer can be reduced.

The maximum height roughness Rz (nm) of inclined planes of the convex shapes of the first optical layer is 3.0 times or less an average thickness (nm) of the metal layer.

In the present specification, the maximum height roughness Rz is Rz specified by JIS B 0601 2001. The standard length is preferably from 1 μm to 3 μm.

A measuring method of the maximum height roughness Rz of inclined planes of the convex shapes of the first optical layer is not particularly limited and may be appropriately selected depending on the intended purpose. Examples of the measuring method include observation under an atomic force microscope (AFM) and observation under a transmission electron microscope (TEM). Note that, obtained results are almost the same whichever microscope (AFM or TEM) is used.

Examples of a control method of the maximum height roughness Rz of inclined planes of the convex shapes of the first optical layer include a method where convex shapes of a first optical layer are produced using a master for transferring shapes, surface roughness of which has been controlled. Examples of a method for controlling the surface roughness of the master for transferring shapes include: a method where even nickel-phosphorous plating having no or small pours is deposited on a master base, such as a SUS roll, and the surface of the nickel-phosphorous plating having no or small pours is subjected to ultraprecision cutting; and a method where cutting is performed on a master base, such as a plated SUS roll, using predetermined cutting tools giving different degrees of abrasion.

The first optical layer may have characteristics that the first optical layer absorbs light of a certain wavelength within the visible region for the purpose of giving designs to an optical member or a window material, as long as the absorption of light does not adversely affect transparency of the first optical layer to visible light.

Giving a design, i.e., characteristics that the first optical layer absorbs light having a certain wavelength within the visible region, can be achieved, for example, by adding a pigment to the first optical layer.

The pigment is preferably dispersed in the resin.

The pigment dispersed in the resin is not particularly limited and may be appropriately selected depending on the intended purpose. Examples of the pigment include inorganic-based pigments and organic-based pigments. The pigment is particularly preferably an inorganic-based pigment where a pigment itself has high weather resistance.

The inorganic-based pigment is not particularly limited and may be appropriately selected depending on the intended purpose. Examples of the inorganic-based pigment include zircon gray (Co and Ni-doped ZrSiO₄), praseodymium yellow (Pr-doped ZrSiO₄), chrome titanium yellow (Cr and Sb-doped TiO₂ or Cr and W-doped TiO₂), chrome green (Cr₂O₃ etc.), peacock ((CoZn)O(AlCr)₂O₃), Victoria green ((Al, Cr)₂O₃), Prussian blue (CoO.Al₂O₃.SiO₂), vanadium zircon blue (V-doped ZrSiO₄), chrome in pink (Cr-doped CaO.SnO₂.SiO₂), manganese pink (Mn-doped Al₂O₃), and salmon pink (Fe-doped ZrSiO₄).

The organic-based pigment is not particularly limited and may be appropriately selected depending on the intended purpose. Examples of the organic-based pigment include azo-based pigments and phthalocyanine-based pigments.

The pitch of the convex shapes of the first optical layer is not particularly limited and may be appropriately selected depending on the intended purpose. The pitch is preferably 300 μm or less, more preferably 200 μm or less, and particularly preferably from 20 μm to 150 μm. When the pitch of the convex shapes of the first optical layer is less than 20 μm, a cutting tool for processing a master is worn to produce rough inclined planes, or an external appearance may be degraded due to optical diffraction. When the pitch of the convex shapes of the first optical layer is greater than 150 μm, moreover, depths of the convex shapes increase along the increase in the pitch, and therefore a thickness of a resulting optical member increases and the optical member may not be bent.

A measuring method of the pitch of the convex shapes of the first optical layer is not particularly limited and may be appropriately selected depending on the intended purpose. Examples of the measuring method include observation under an optical microscope and cross-section observation under SEM.

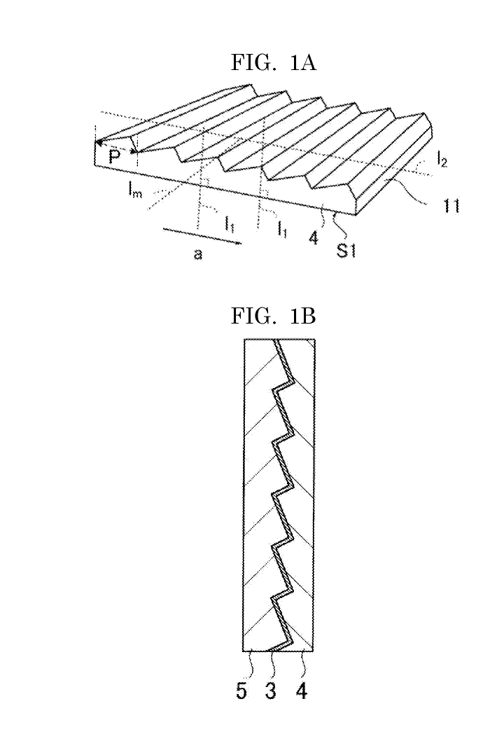

The pitch of the convex shapes of the first optical layer indicates P in FIG. 1A. Specifically, the pitch is a distance between one edge of one apex of the convex shapes and the other edge of the apex. In the case where a plurality of different pitches are included in the convex shapes, the pitch is an average value of the pitches.

A shape of the first optical layer is not particularly limited and may be appropriately selected depending on the intended purpose. Examples of the shape include a film shape, a sheet shape, a plate shape, and a block shape. The first optical layer has preferably a film shape or a sheet shape considering that a resulting optical member can be easily bonded to a window material.

The convex shapes of the first optical layer are formed with either a one-dimensional alignment or two-dimensional alignment of a plurality of structures. The structures are not particularly limited and may be appropriately selected depending on the intended purpose. Examples of the structures include prism structures, lenticular structures, hemispherical structures, and corner cube structures.

As illustrated in FIG. 1A, moreover, a shape of the structure 11 may be an asymmetric shape relative to perpendicular line l₁ perpendicular to the incident surface S1 of the optical member. In this case, the main axis lₘ of the structure is inclined to the aligned direction a of the structure with the perpendicular line l₁ being a standard. In the present specification, the main axis lₘ of the structure means a straight line passing through a middle point of the bottom side of the cross-section of the structure 11 and an apex of the structure 11. In the case where the optical member is bonded to a window material arranged perpendicular to the ground, the main axis lₘ of the structure 11 is preferably inclined to the bottom side (the ground side) of the window material with the perpendicular line l₁ being a standard, as illustrated in FIG. 1B. The period that the amount of heat transmitted through windows is large is typically about noon or later, and the angle of the sun is often higher than 45° during this period. Therefore, the light incident from the high angle can be efficiently reflected to the upper side by adapting the shape as illustrated in FIG. 1A. FIGS. 1A and 1B illustrate the examples where the prism-shaped structures 11 are asymmetric relative to the perpendicular line l₁. Note that, the structures 11 having shapes other than the prism shapes may be used and such the structures 11 for use may be asymmetric to the perpendicular line l₁. For example, corner cubes may be used and may be asymmetric to the perpendicular line l₁.

Moreover, one shape of the structures 11 may be used or two or more shapes of the structures 11 may be used in combination. In the case where a plurality of shapes of structures are disposed at a surface of the first optical layer, the structures may be arranged in a manner that the predetermined pattern composed of the plurality of the shapes of the structures is periodically repeated. Moreover, the plurality of shapes of the structures may be randomly (aperiodically) arranged depending on the desired characteristics.

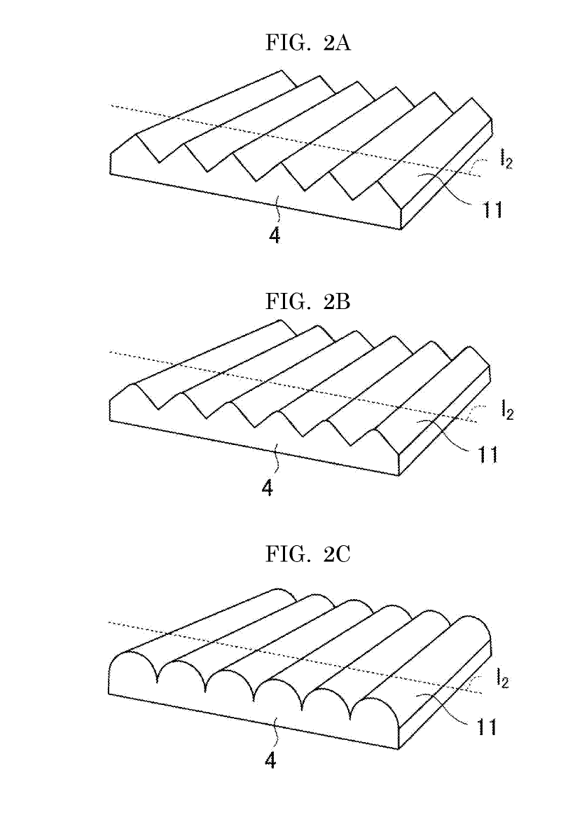

FIGS. 2A to 2C are perspective views illustrating examples of shapes of the structures contained in the first optical layer. The structure 11 is a convex pillar extending one direction. The pillar-shaped structures 11 are one-dimensionally arranged along one direction. Since a reflective layer is formed on the structures, a shape of the reflective layer is identical to the surface shape of the structures 11.

In FIGS. 1A, 1B, 2A, 2B, and 2C, reference numeral 3 is a reflective layer, reference numeral 4 is a first optical layer, and reference numeral 5 is a second optical layer. Hereinafter, the same members are assigned with the same numerical reference in the drawings of the present specification.

<Reflective Layer>

The reflective layer contains at least a metal layer, preferably further contains a high refractive index layer, and may further contain other layers according to the necessity.

The reflective layer is formed on the convex shapes of the first optical layer.

The reflective layer reflects light including at least infrared light.

The average thickness of the reflective layer is not particularly limited and may be selected depending on the intended purpose. The average thickness is preferably 20 μm or less, more preferably 5 μm or less, and particularly preferably 1 μm or less. When the average thickness of the reflective layer is greater than 20 μm, a light path where transmitted light is refracted becomes long and thus a transmission image tends to be seen deformed.

<<Metal Layer>>

A material of the metal layer is not particularly limited and may be appropriately selected depending on the intended purpose. Examples of the material include single metals and alloys.

The single metals are not particularly limited and may be appropriately selected depending on the intended purpose. Examples of the single metals include Au, Ag, Cu, Al, Ni, Cr, Ti, Pd, Co, Si, Ta, W, Mo, and Ge.

The alloys are not particularly limited and may be appropriately selected depending on the intended purpose. The alloys are preferably Ag-based materials, Cu-based materials, Al-based materials, Si-based materials, or Ge-based materials, and more preferably AlCu, AlTi, AlCr, AlCo, AlNdCu, AlMgSi, AgPdCu, AgPdTi, AgCuTi, AgPdCa, AgPdMg, or AgPdFe. Moreover, a material, such as Ti and Nd, is preferably added to the metal layer in order to prevent corrosion of the metal layer. Especially when Ag is used as a material of the metal layer, addition of Ti or Nd to the metal layer is preferable.

The average thickness of the metal layer is 40 nm or less, preferably from 5 nm to 30 nm, and more preferably from 7 nm to 20 nm.

The maximum height roughness Rz (nm) of inclined planes of the convex shapes is 3.0 times or less, preferably 2.0 times or less, and more preferably 1.0 time or less the average thickness (nm) of the metal layer.

In the case where the reflective layer includes high refractive index layers and metal layers laminated alternately and has a plurality of the metal layers, the maximum height roughness Rz (nm) of inclined planes of the convex shapes is 3.0 times or less the average thickness (nm) of the thinnest metal layer.

A measuring method of the average thickness of the metal layer is not particularly limited and may be appropriately selected depending on the intended purpose. Examples of the measuring method include a measurement through observation under a transmission electron microscope (TEM). A TEM observation is performed on a center of an area where the inclination of the convex shape is the mildest, and a thickness of the area of the metal layer where the width is the smallest is measured at 3 positions within the area where the metal layer is clearly observed. The average value of the measured values is determined as the average thickness.

A formation method of the metal layer is not particularly limited and may be appropriately selected depending on the intended purpose. Examples of the formation method include sputtering, vapor deposition, chemical vapor deposition (CVD), dip coating, die coating, wet coating, and spray coating.

The metal layer is preferably formed evenly. In the present specification, being even means that the maximum width of the metal layer observed does not exceed 3 times the average thickness of the metal layer, and being uneven means that the maximum width of the metal layer observed is 3.0 times or greater the average thickness of the metal layer.

When the maximum width of the metal layer that can be observed is 3.0 times or greater (uneven) the average thickness of the metal layer, durability of a resulting optical member is insufficient. When the metal layer is uneven, the progress of deterioration is considered to accelerate due to an increase in the surface area, and easiness of moisture or other materials to enter.

A even metal layer can be formed by adjusting the maximum height roughness Rz (nm) of the inclined plane of the convex shapes to 3.0 times or less the average thickness (nm) of the metal layer.

<<High Refractive Index Layer>>

The high refractive index layer is a layer that has a high refractive index in a visible region, and functions as an antireflection layer. A material of the high refractive index layer is not particularly limited and may be appropriately selected depending on the intended purpose. Examples of the material include metal oxides and metal nitrides. The metal oxides are not particularly limited and may be appropriately selected depending on the intended purpose, and examples of the metal oxides include niobium oxide, tantalum oxide, and titanium oxide. The metal nitrides are not particularly limited and may be appropriately selected depending on the intended purpose, and examples of the metal nitrides include silicon nitride, aluminium nitride, and titanium nitride.

For example, the high refractive index means a refractive index of 1.7 or higher.

The average thickness of the high refractive index layer is not particularly limited and may be appropriately selected depending on the intended purpose. The average thickness is preferably from 10 nm to 300 nm, more preferably from 15 nm to 200 nm, and particularly preferably from 20 nm to 150 nm.

A measuring method of the average thickness of the high refractive index layer is not particularly limited and may be appropriately selected depending on the intended purpose. Examples of the measuring method include AFM observation and TEM observation.

A formation method of the high refractive index layer is not particularly limited and may be appropriately selected depending on the intended purpose. Examples of the formation method include sputtering, vapor deposition, chemical vapor deposition (CVD), dip coating, die coating, wet coating and spray coating.

<Other Layers>

The above-mentioned other layers are not particularly limited and may be appropriately selected depending on the intended purpose. Examples of the above-mentioned other layers include a second optical layer and a functional layer.

<<Second Optical Layer>>

For example, the second optical layer has recess shapes to fill the convex shapes of the first optical layer.

The second optical layer is a layer configured to improve clarity of transmitted images or a total light transmittance, as well as protecting the reflective layer. A material of the second optical layer is not particularly limited and may be appropriately selected depending on the intended purpose. Examples of the material include resins, such as thermoplastic resins (e.g., polycarbonate) and active energy ray-curable resin (e.g., acryl). Moreover, the second optical layer may function as an adhesive layer, a resulting optical member may have a structure where the optical member is bonded to a window material via the adhesive layer. A material of the adhesive layer is not particularly limited and may be appropriately selected depending on the intended purpose. Examples of the material include pressure sensitive adhesives (PSA) and ultraviolet ray-curing resins.

The second optical layer may have characteristics that the second optical layer absorbs light of a certain wavelength within the visible region for the purpose of giving designs to an optical member or a window material, as long as the absorption of light does not adversely affect transparency of the second optical layer to visible light.

Giving a design, i.e., characteristics that the second optical layer absorbs light having a certain wavelength within the visible region, can be achieved, for example, by adding a pigment to the second optical layer.

The pigment is preferably dispersed in the resin.

The pigment dispersed in the resin is not particularly limited and may be appropriately selected depending on the intended purpose, and examples of the pigment include the pigments listed as examples in the descriptions of the first optical layer.

A difference in a refractive index between the first optical layer and the second optical layer is not particularly limited and may be appropriately selected depending on the intended purpose, but the difference is preferably 0.010 or less, more preferably 0.008 or less, and particularly preferably 0.005 or less. When the difference in the refractive index is greater than 0.010, a transmitted image may appear blurred. When the difference in the refractive index is greater than 0.008 but 0.010 or less, there is no problem with lighting in ordinary life although it depends on brightness of outside. When the difference in the refractive index is greater than 0.005 but 0.008 or less, outer sceneries can be clearly seen although diffraction patterns are observed on only extremely blight objects, such as light sources. Diffraction patterns are almost unnoticeable when the difference in the refractive index is 0.005 or less. Among the first optical layer and the second optical layer, the optical layer disposed at the side of the optical member to be bonded, such as the side bonded with window material, may contain a pressure sensitive adhesive as a main component. Since the optical layer has the above-described structure, the optical member can be bonded to a window material, etc. with the optical layer containing the pressure sensitive adhesive as a main component.

The first optical layer and the second optical layer preferably have the same optical properties, such as a refractive index. More specifically, the first optical layer and the second optical layer are composed of the same material having transparency in the visible region. The refractive indexes of the first optical layer and the second optical layer can be made identical by forming the first optical layer and the second optical layer using the same material, and therefore transparency of the optical member with visible light can be improved. However, attentions should be paid because a refractive index of a final film may be different depending on curing conditions in film forming process, even though the formation of the film is started with the same material. When the first optical layer and the second optical layer are formed using mutually different materials, on the other hand, refractive indexes of the first optical layer and the second optical layer are different. Therefore, light is refracted at the reflective layer as a boundary, and a transmission image tends to be blurred. Particularly, there is a problem that a diffraction pattern is significantly observed when an object close to a point light source, such as an electric light, present far.

The first optical layer and the second optical layer preferably have transparency in the visible region. In the present specification, the definition of transparency has two meanings. One is that absorption of light is small, and the other is that scattering of light is small. The transparency typically denotes only the former, but the transparency preferably denotes the both in the present invention. Currently used retroreflectors, such as road signs and night-shift work clothes, aim to visualize displayed reflected light, and therefore the reflected light can be visualized as long as the retroreflectors are in contact with the underlying reflectors, even though the retroreflectors have, for example, scattering. This is the same principle to, for example, that an image can be visualized even when antiglare treatment is performed on a front surface of an image display device for the purpose of providing anti-glare properties. However, the optical member of the present invention is characterized in that the optical member passes through light other than light having a certain wavelength range that causes directional reflection, the optical member is adhered to a transparent body that mainly transmits the transmissive wavelengths to observe the transmitted light. Therefore, it is necessary that there is no scattering of light. However, scattering properties can be intentionally applied only to the second optical layer depending on the intended use.

<<Functional Layer>>

The functional layer is not particularly limited and may be appropriately selected depending on the intended purpose, as long as the functional layer is a layer containing, as a main ingredient, a chromic material that reversibly changes reflection characteristics upon application of external stimula.

The chromic material is not particularly limited and may be appropriately selected depending on the intended purpose, as long as the chromic material is a material that reversibly changes a structure upon application of external stimula, such as heat, light, and penetrating molecules. Examples of the chromic material include photochromic materials, thermochromic materials, and electrochromic materials.

An arrangement position of the functional layer is not particularly limited and may be appropriately selected depending on the intended purpose.

The optical member has transparency. The transparency is preferably transparency having the range of the below-described clarity of transmitted images.

The optical member is preferably used by bonding to a rigid body (e.g., a window material) having transparency to mainly light, which is other than light having a certain wavelength range, transmitted via a pressure sensitive adhesive. The window material is not particularly limited and may be appropriately selected depending on the intended purpose. Examples of the window material include window materials for building, such as skyscrapers and houses, and window materials for vehicles. In the case where the optical member is applied for the window material for buildings, the optical member is particularly preferably applied for a window material arranged towards any of the directions between east and west via south (e.g., south east to south west). Since the window material is applied at the aforementioned position, heat rays can be more effectively reflected. The optical member can be used not only on a single-layer glass window, but also on special glass, such as multi-layer glass. Moreover, the window material is not limited to a material formed of glass, and a material formed of a polymer material having transparency may be used as the window material. When the first optical layer and the second optical layer have transparency in the visible region, visible light is transmitted, and lighting can be secured from sunlight in the case where the optical member is bonded to the window material, such as a glass window. Moreover, a surface to which the optical member is bonded is not only an outer surface of glass but also an inner surface of glass. In the case where the optical member is bonded to the inner surface of the glass, the optical member needs to be bonded in the manner that the front and back of the convex and concave of structures and the in-plane direction are aligned to make the directional reflection direction the predetermined direction.

The optical member preferably has flexibility considering that the optical member can be easily bonded to a window material. A shape of the optical member is not particularly limited and may be appropriately selected depending on the intended purpose. Examples of the shape include a film shape, a sheet shape, a plate shape, and a block shape. However, the shape of the optical member is not limited to the above-listed examples.

Moreover, the optical member can be used in combination with other heat ray-cut films. For example, a light-absorbing film can be disposed at an interface between the air and the first optical layer. Moreover, the optical member can be also used in combination with a hard coating layer, a UV-cut layer, or a surface antireflection layer. In the case where there functional layers are used in combination, these functional layers are preferably disposed at an interface between the optical member and the air. However, the UV-cut layer needs to be disposed closer to the side of sun than the optical member. In the case where the optical member is bonded to an inner surface of a glass window for outdoor or indoor use, particularly, the UV-cut layer is desirably disposed between the inner surface of the glass window and the optical member. In this cases, an ultraviolet ray-absorbing agent may be kneaded into a pressure sensitive adhesive layer between the surface of the glass window and the optical member.

Moreover, color may be applied to the optical member depending on the intended use of the optical member to give a design to the optical member. In the case where a design is provided as described, the optical member preferably has a structure where the optical layer absorbs only light having a certain wavelength range as long as transparency of the optical member is not impaired.

<Functions of Optical Member>

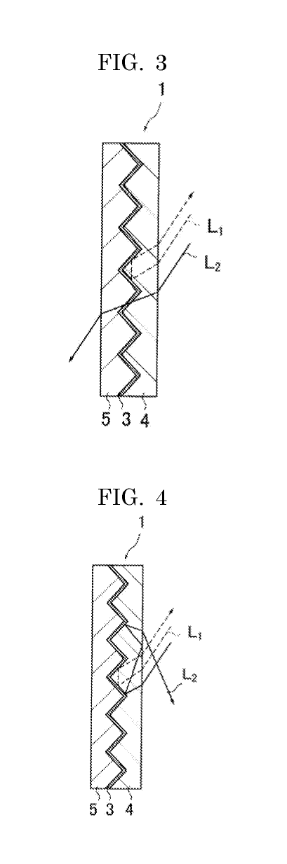

FIGS. 3 and 4 are cross-sectional views for explaining one example of functions of the optical member. In the present specification, a case where a shape of each structure is a prism shape having an inclined angle of 45° is taken as an example, and such an example is explained.

As illustrated in FIG. 3, among the sunlight incident to the optical member 1, whereas part of light L₁ reflecting to the sky is reflected directionally to the direction of the sky similar to the incident direction, light L₂ not reflecting to the sky, transmits the optical member 1.

As illustrated in FIG. 4, moreover, light, which incidents on the optical member 1 and is reflected with a reflective film surface of the reflective layer 3, is separated into light L₁ reflecting to the sky and light L₂ not reflecting to the sky at a ratio depending on the incident angle. The light L₂ not reflecting to the sky is totally reflected at an interface between the second optical layer 5 and the air, then finally reflected to the direction different from the incident direction.

When the incident angle of light is α, the refractive index of the first optical layer 4 is n, and the reflectance of the reflective layer is R, a ratio x of the light L₁ reflecting to the sky relative to the total incident components is represented by the following formula (1).

x=(sin(45−α′)+cos(45−α′)/tan(45+α′))/(sin(45−α′)+cos(45−α′))×R² Formula (1)

With the proviso that, α′=sin⁻¹(sin α/n)

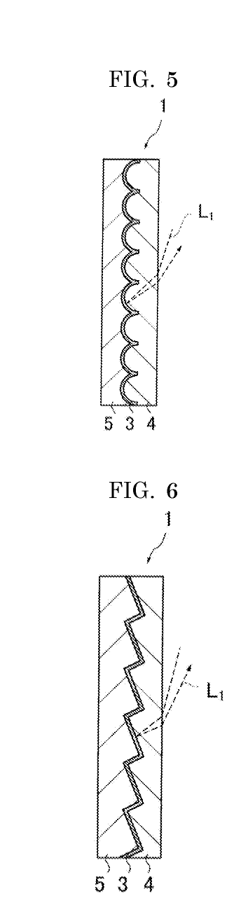

As the ratio of the light L₂ not reflecting to the sky increases, the ratio of the incident light reflecting to the sky decreases. In order to improve the ratio of the light reflecting to the sky, it is effective to modify the shape of the reflective layer 3, namely, the shapes of the structures of the first optical layer 4. In order to improve the ratio of the light reflecting to the sky, for example, the shapes of the structures 11 are cylindrical shapes illustrated in FIG. 2C, or asymmetric shapes illustrated in FIGS. 1A and 1B. Since the structures have the above-mentioned shapes, the ratio of the light reflecting to the upper side relative to the light incident on a window material for buildings from the upper side can be increased even through the light cannot be reflected to the identical direction to the incident light. The two shapes illustrated in FIGS. 2C, 1A and 1B can achieve that the number of reflections of the incident light with the reflective layer 3 is once, as illustrated in FIGS. 5 and 6. Therefore, the final reflection component can be increased compared to the shapes with which light is reflected twice as illustrated in FIG. 3. In the case where the material that reflects light twice is used, for example, the reflectance to the sky is 64%, when the reflectance of the reflective layer to the certain wavelengths is 80%. If the reflection occurs only once, the reflectance to the sky becomes 80%.

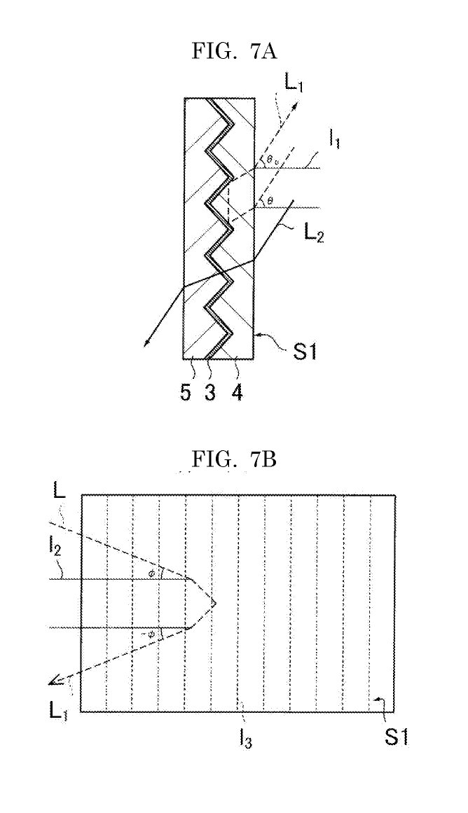

FIGS. 7A and 7B illustrates a relationship between the ridge line l₃ of a pillar-shaped structure, incident light L, and light L₁ reflected to the sky. The optical member preferably transmits light L₂ not reflecting to the sky, amount the incident light L incident on the incident surface S1 at the incident angle (θ, φ), whereas the optical member selectively directionally reflects light L₁ reflecting to the sky in the direction of (θo, −φ) (0°<θo<90°). Since the above-described relationship is satisfied, light having a certain wavelength range can be reflected to the sky direction. Note that, θ is an angle formed between the perpendicular line l₁ relative to the incident surface S1 and the incident light L or the light L₁ reflecting to the sky; and φ is an angle formed between the straight line l₂ orthogonal to the ridge line l₃ of the pillar-shaped structure within the incident surface S1, and the incident light L or a component obtained by projecting the light L₁ reflecting to the sky onto the incident surface S1. Note that, the angle θ rotated clockwise with the perpendicular line l₁ as the standard is determined as “+θ,” and the angle θ rotated anticlockwise with the perpendicular line l₁ is determined as “−θ”; and the angle φ rotated clockwise with the straight line l₂ as the standard is determined as “+φ)” and the angle φ rotated anticlockwise with the straight line l₂ as the standard is determined as “−φ.”

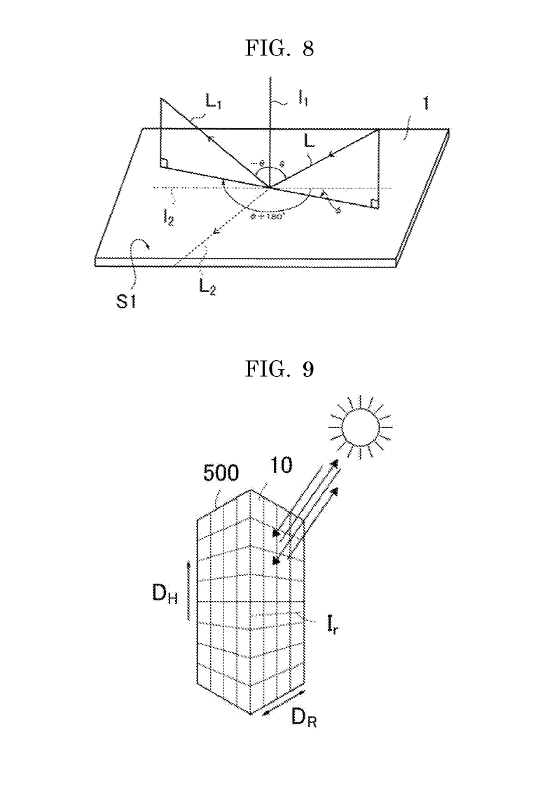

FIG. 8 is a perspective view illustrating the relationship between the incident light entering the optical member 1 and the reflected light reflected by the optical member. The optical member has the incident surface S1 on which the incident light L is applied. The optical member 1 transmits the light L₂ not reflecting to the sky among the incident light L incident on the incident surface S1 at the incident angle (θ, φ), whereas the optical member 1 selectively directionally reflect the light L₁ reflecting to the sky to the direction other than the direction of regular reflection (−θ, +180°). Moreover, the optical member 1 has transparency to light other than the light having the certain wavelength range. The transparency is preferably transparency having the below-mentioned range of clarity of transmitted images. Note that, θ is an angle formed between the perpendicular line l₁ relative to the incident surface S1 and the incident light L or the light L₁ reflecting to the sky; and φ is an angle formed between the certain straight line l₂ within the incident surface S1, and the incident light L or a component obtained by projecting the light L₁ reflecting to the sky onto the incident surface S1. In the present specification, the certain straight l₂ within the incident surface is an axis with which the reflection intensity to the direction of φ becomes the maximum, when the incident angle (θ, φ) is fixed, and the optical member is rotated using the perpendicular line l₁ relative to the incident surface S1 of the optical member as an axis (see FIGS. 1A to 1B, and FIGS. 2A to 2C). In the case where there are plurality of axes (directions) with which the reflection intensity becomes the maximum, one of the axis is selected as the straight line l₂. Note that, the angle θ rotated clockwise with the perpendicular line l₁ as the standard is determined as “+θ,” and the angle θ rotated anticlockwise with the perpendicular line l₁ is determined as “−θ”; and the angle φ rotated clockwise with the straight line l₂ as the standard is determined as “+φ” and the angle φ rotated anticlockwise with the straight line l₂ as the standard is determined as “−φ.”

The light having a certain wavelength range, which is selectively directionally refracted, and the certain light transmitted are different depending on the intended use of the optical member. In the case where the optical member is applied for a window material, for example, the light having a certain wavelength range, which is directionally reflected, preferably includes at least near infrared light, and the light having a certain wavelength, which is transmitted, is preferably visible light. Specifically, the light having a certain wavelength range, which is selectively directionally reflected, is preferably near visible light and infrared light having a main wavelength range of 400 nm to 2,100 nm, more preferably near infrared rays of 780 nm to 2,100 nm. Since the near infrared rays are reflected, an increase in a temperature within a building can be prevented, when the optical member is bonded to a window material, such as a glass window. Accordingly, loads of air conditioners can be reduced, and energy saving can be achieved. In the present specification, the directional reflection means that the intensity of the reflected light to the certain direction other than regular reflection is stronger than the intensity of regularly reflected light, and is sufficiently stronger than the intensity of diffuse reflection with no directivity. In the present specification, to reflect means that the reflectance in the certain wavelength range, such as the near infrared range, is preferably 30% or greater, more preferably 50% or greater, and even more preferably 80% or greater. To transmit means that the transmittance in the certain wavelength range, such as the visible range, is preferably 15% or greater, more preferably 50% or greater, and even more preferably 70% or greater.

The direction φo of the directional reflection with the optical member is preferably −90° or greater but 90° or less. This is because the light having the certain wavelength range among the light incident from the sky can be returned to the sky direction, when the optical member is bonded to a window material. In the case where there is no tall buildings in the surrounding area, the optical member having the above-mentioned range is effective. Moreover, the direction of the directional reflection with the optical member is preferably adjacent to (θ, −φ). The adjacent is preferably within 5 degrees, more preferably within 3 degrees, and particularly preferably within 2 degrees from (θ, −φ). Since the direction of the directional reflection is within the above-mentioned range, among the light incident from the sky of a building in the area where the buildings of similar heights are present, the light having the certain wavelength range can be efficiently return back to the sky of other buildings, when the optical member is bonded to a window material. In order to the above-mentioned directional reflection, three-dimensional structures, such as spherical surfaces, part of hyperboloids, triangular pyramids, square pyramids, and cones, are preferably used as the structures. The light incident from the (θ, φ) direction (−90°<φ<90°) can be reflected to the (θo, φo) direction (0°<θo<90°, −90°<φo<90°) depending on the shapes of the structures. Alternatively, the structures are preferably pillars extending along one direction. The light incident from the (θ, φ) direction (−90°<φ<90°) can be reflected to the (θo, −φ) direction (0°<θo<90°) depending on the inclined angle of the pillar.

The directional reflection of the light having a certain wavelength range with the optical member is preferably the direction adjacent to retroreflection (specifically, the reflection direction of the light having a certain wavelength range is adjacent (θ, φ), relative to the light incident on the incident surface S1 at the incident angle (θ, φ). This is because the optical member can return the light having a certain wavelength range to the sky among the light incident from the sky, when the optical member is bonded to a window material. In the present specification, the adjacent is preferably within 5 degrees, more preferably within 3 degrees, and particularly preferably within 2 degrees. Since the direction is within the above-mentioned range, the light having a certain wavelength range can be efficiently returned to the sky among the light incident from the sky, when the optical member is bonded to a window materials. Moreover, in the case where an infrared light irradiation unit and a light receiving unit are adjacent to each other, such as infrared sensors or infrared imaging devices, a retroreflection direction needs to be identical to an incident direction. In the case where it is not necessary to perform sensing from a certain direction, as in the present invention, the retroreflection direction and the incident direction do not need to be strictly the same direction.

A value of the optical member when an optical comb of 0.5 mm is used to determine clarity of a transmitted image with light having a wavelength range having transparency is not particularly limited and may be appropriately selected depending on the intended purpose, but the value is preferably 50 or greater, more preferably 60 or greater, and particularly preferably 75 or greater. When the value of the clarity of the transmitted image is less than 50, the transmission image tends to be seen blurred. When the value of the clarity of the transmitted image is 50 or greater but less than 60, there is no problem with lighting in ordinary life although it depends on brightness of outside. When the value of the clarity of the transmitted image is 60 or greater but less than 75, outer sceneries can be clearly seen although diffraction patterns are observed on only extremely blight objects, such as light sources. When the value of the clarity of the transmitted image is 75 or greater, diffraction patterns are almost unnoticeable. Furthermore, a total value of the clarity of the transmitted image measured using the optical combs of 0.125 mm, 0.5 mm, 1.0 mm, and 2.0 mm is not particularly limited and may be appropriately selected depending on the intended purpose, but the total value is preferably 230 or greater, more preferably 270 or greater, and particularly preferably 350 or greater. When the total value of the clarity of the transmitted image is less than 230, the transmission image tends to appear blurred. When the total value of the clarity of the transmitted image is 230 or greater but less than 270, there is no problem with lighting in ordinary life although it depends on brightness of outside. When the total value of the clarity of the transmitted image is 270 or greater but less than 350, outer sceneries can be clearly seen although diffraction patterns are observed on only extremely blight objects, such as light sources. When the total value of the clarity of the transmitted image is 350 or greater, diffraction patterns are almost unnoticeable. In the present specification, the value of the clarity of the transmitted image is a value measured by means of ICM-1T available from Suga Test Instruments Co., Ltd. according to JIS K7105. In the case where the wavelength to be transmitted is different from a wavelength of a light source D65, the measurement is preferably performed after calibrating the light using a filter for a wavelength to be transmitted.

The haze of the optical member to the light having the wavelength range having transparency is not particularly limited and may be appropriately selected depending on the intended purpose, but the haze is preferably 6% or less, more preferably 4% or less, and particularly preferably 2% or less. When the haze is greater than 6%, the transmitted light is scattered, and the optical member appears cloudy. In the present specification, the haze is a value measured using HM-150 available from MURAKAMI COLOR RESERCH LABORATORY according to the measuring method specified in JIS K7136. In the case where the wavelength to be transmitted is different from a wavelength of a light source D65, the measurement is preferably performed after calibrating the light using a filter for a wavelength to be transmitted.

The incident surface S1 of the optical member, preferably the incident surface S1 and the light-emitting surface S2 of the optical member, preferably have a degree of smoothness that does not reduce the clarity of the transmitted image. Specifically, the arithmetic average roughness Ra of the incident surface S1 and the light-emitting surface S2 is not particularly limited and may be appropriately selected depending on the intended purpose, but the arithmetic average roughness Ra is preferably 0.08 μm or less, more preferably 0.06 μm or less, and particularly preferably 0.04 μm or less. Note that, the arithmetic average roughness Ra is a value obtained by measuring surface roughness of the incident surface, obtaining a roughness curve from the two-dimensional cross-section curve, and calculating as a roughness parameter. Note that, the measuring conditions are according to JIS B0601:2001. The measuring device and measuring conditions are described below.

Measuring device: automatic microfigure measuring instrument (SURFCORDER ET4000A, available from Kosaka Laboratory Ltd.)
λc=0.8 mm, evaluation length: 4 mm, cut-off: ×5
data sampling gap: 0.5 μm

The transmission color of the optical member is preferably as neutral as possible, and even when the optical member is tinted, the transmission color is preferably a pale color tone, such as blue, blueish green, and green, which gives refreshing feeling. In order to obtain the above-mentioned color tone, chromaticity coordinates x and y of the transmitted light entered from the incident surface S1, passed through the optical layer and the reflective layer, and emitted from the light-emitting surface S2, and the reflected light, for example, by radiation of the D65 light source, is not particularly limited and may be appropriately selected depending on the intended purpose, but the chromaticity coordinates are preferably 0.20<x<0.35 and 0.20<y<0.40, more preferably 0.25<x<0.32 and 0.25<y<0.37, and particularly preferably 0.30<x<0.32 and 0.30<y<0.35. In order to avoid a reddish color tone, the chromaticity coordinates are preferably y>x−0.02, and more preferably y>x. If a color tone of reflection changes depending on an incident angle, for example in the case where the optical member is applied for a window of a building, the color tone is different depending on a location, and the color seen by people changes as the people walk. Therefore, such change of color tone is not preferable. In view of preventing the change of color tone, an absolute value of a difference in the color coordinate x and an absolute value of difference in the color coordinate y of the regularly reflected light, which enters from the incident surface S1 or light-emitting surface S2 at an incident angle θ of 0° or greater but 60° or less and reflected by the first optical layer, the second optical layer, and the reflective layer are not particularly limited and may be appropriately selected depending on the intended purpose on the both surfaces of the optical member, but the absolute values are preferably 0.05 or less, more preferably 0.03 or less, and particularly preferably 0.01 or less. The above-described numeral ranges associates with the color coordinates x and y of the reflected light are desirably satisfied on both surfaces of the incident surface S1 and the light-emitting surface S2.

(Window Material)

A window material of the present invention includes the optical member of the present invention.

The window material is not particularly limited and may be appropriately selected depending on the intended purpose. Examples of the window materials include window materials for buildings, such as skyscrapers and housings, and window materials for vehicles. In the case where the optical member is applied for the window material for buildings, the optical member is particularly preferably applied for a window material arranged towards any of the directions between east and west via south (e.g., south east to south west). Since the window material is applied at the aforementioned position, heat rays can be more effectively reflected.

FIG. 9 illustrates one example of a building 500, in which an optical member 1 is bonded to a window material 10 in a manner that ridge line direction D_{R} of the convex shapes of the first optical layer within the incident surface of the optical member 1 is to be substantially perpendicular to the height direction D_{H} of the building. In the case where the optical member 1 is bonded to the window material 10 in the above-described manner, a reflection performance of the optical member 1 can be effectively exhibited. Therefore, majority of light incident on the window material 10 from the upper side can be reflected to the upper side. Accordingly, the upper reflectance of the window material 10 can be improved.

(Joinery)

Joinery of the present invention include a light collection part from which sunlight enters, and the light collection part includes the optical member of the present invention.

The joinery is not particularly limited and may be appropriately selected depending on the intended purpose, and examples of the joinery include glass doors, sliding screens, and shutters.

In the case where the joinery is a glass door, for example, the light collection part denotes a glass part that is a part removing a sash part from the glass door.

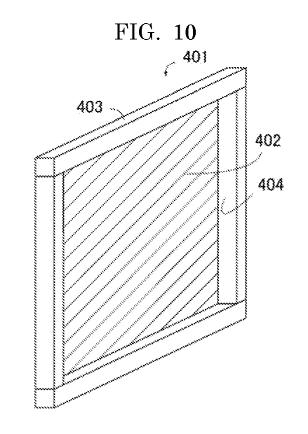

FIG. 10 is a perspective view illustrating one structural example of the joinery. As illustrated in FIG. 10, the joinery 401 has a structure where the light collection part 404 include an optical member 402. Specifically, the joinery 401 includes the optical member 402 and a frame material 403 arranged around the periphery of the optical member 402. The optical member 402 is fixed with the frame material 403. The optical member 402 can be optionally taken out by dismantling the frame material 403. Examples of the joinery 401 include sliding screens, but the joinery is not limited to the above-listed example, and can be applicable for various joinery having light collection parts.

(Production Method of Optical Member)

A production method of an optical member of the present invention includes at least a first optical layer forming step and a reflective layer forming layer, and may further include other steps according to the necessity.

<First Optical Layer Forming Step>

The first optical layer forming step is not particularly limited and may be appropriately selected depending on the intended purpose, as long as the first optical layer forming step is a step for forming a first optical layer having convex shapes using a transfer master having concave shapes.

In the first optical layer forming step, roughness of the convex shapes (e.g., maximum height roughness Rz) can be controlled by controlling surface roughness of the transfer master having concave shapes when the first optical layer having the convex shapes is formed using the transfer master having the convex shapes (may be referred to as a “master for transferring shapes” or a “mold” hereinafter). In the present invention, the maximum height roughness Rz of inclined planes of the convex shapes is 3.0 times or less the average thickness of the metal layer. The above-mentioned condition can be achieved by controlling the surface roughness of the transfer master having convex shapes.

Examples of a method for controlling the surface roughness of the transfer master having concave shapes include: a method where even nickel-phosphorous plating having no or small pours is deposited on a master base, such as a SUS roll, and the surface of the nickel-phosphorous plating having no or small pours is subjected to ultraprecision cutting; and a method where cutting is performed on a master base, such as a plated SUS roll, using predetermined cutting tools giving different degrees of abrasion.

<Reflective Layer Forming Step>

The reflective layer forming step is not particularly limited and may be appropriately selected depending on the intended purpose, as long as the reflective layer forming step is a step for forming a reflective layer on the first optical layer.

<Second Optical Layer Forming Step>

The second optical layer forming step is not particularly limited and may be appropriately selected depending on the intended purpose, as long as the second optical layer forming step is a step for forming a second optical layer on the reflective layer. Examples of the second optical layer forming step include a step, which an active energy ray-curable resin is applied onto the reflective layer and the cured.

Another example of the production method of an optical member is described.

A even nickel-phosphorous plating film having no or small pours is formed on a master base, such as a SUS roll, and the plated surface is cut by cutting using a cutting tool, ultraprecision cutting, or laser processing to prepare a master for transferring shapes (may be referred to as a “mold” hereinafter) having identical convex shapes to structures, or reverse shapes of the convex shapes.

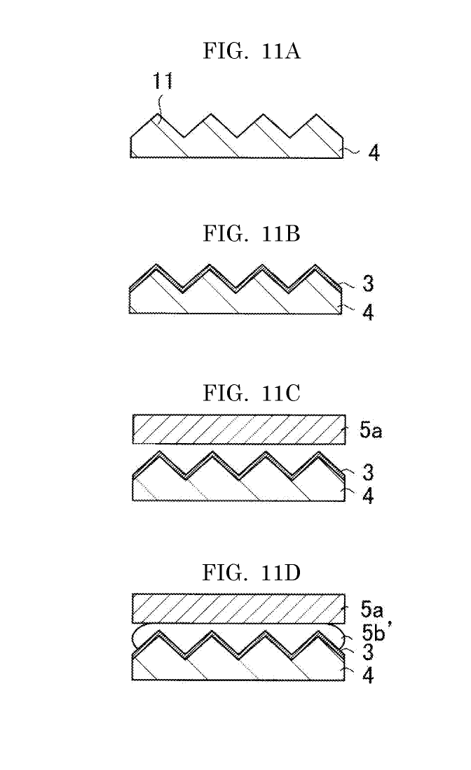

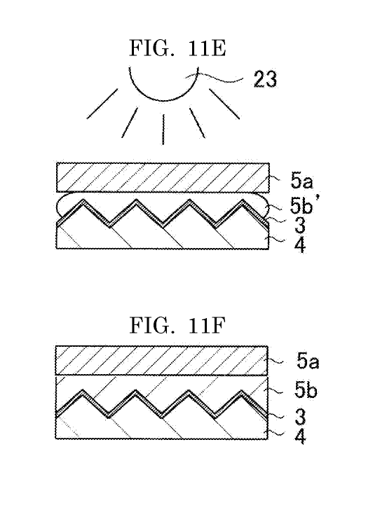

Next, the convex shapes of the mold are transferred to a film-shaped or sheet-shaped resin material, for example, by melt extrusion, or transferring. Examples of the transferring include: a method where an active energy ray-curable resin composition is flown into a mold, and active energy rays are applied to cure the active energy ray-curable resin composition; and a method where heat or pressure is applied to a resin to transfer shapes. As a result, a first optical layer 4 having structures 11 on a main surface of the first optical layer 4 is formed as illustrated in FIG. 11A.

Next, a reflective layer 3 is formed on a main surface of the first optical layer 4 as illustrated in FIG. 11B. Examples of a formation method of a metal layer of the reflective layer 3 include sputtering, vapor deposition, chemical vapor deposition (CVD), dip coating, die coating, wet coating, and spray coating. Examples of a formation method of a high refractive index layer of the reflective layer 3 include sputtering, vapor deposition, chemical vapor deposition (CVD), dip coating, die coating, wet coating, and spray coating.

Next, a base 5a is arranged above the reflective layer 3 to form a nip as illustrated in FIG. 11C.

Next, a resin 5b′, which is an active energy ray-curable resin, is supplied into the nip, as illustrated in FIG. 11D.

Next, UV light is applied to the resin 5b′ over the base 5a by means of a light source 23 to cure the resin 5b′, as illustrated in FIG. 11E.

As a result, a second optical layer 5 having a smooth surface is formed on the reflective layer 3, as illustrated in FIG. 11F.

As described above, the optical member, in which the reflective layer 3 of the predetermined shape is disposed, is obtained.

Another example of the production method of an optical member is described.

A even nickel-phosphorous plating film having no or small pours is formed on a master base, such as a SUS roll, and the plated surface is cut by cutting using a cutting tool, ultraprecision cutting, or laser processing to prepare a mold having identical convex shapes to structures, or reverse shapes of the convex shapes.

Next, the convex shapes of the mold are transferred to a film-shaped or sheet-shaped resin material, for example, by melt extrusion, or transferring. Examples of the transferring include: a method where an active energy ray-curable resin composition is flown into a mold, and active energy rays are applied to cure the active energy ray-curable resin composition; and a method where heat or pressure is applied to a resin to transfer shapes. As a result, a first optical layer having structures of convex shapes on a main surface of the first optical layer is formed.

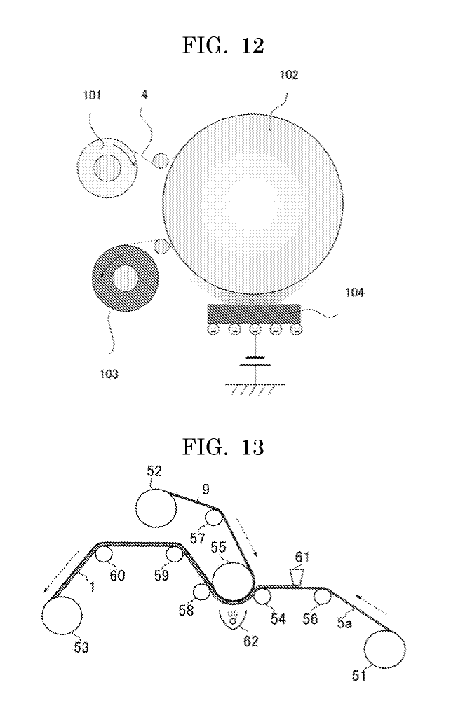

A first optical layer with a reflective layer is produced by means of a production device illustrated in FIG. 12 in the following manner.

The production device illustrated in FIG. 12 is a production device for sputtering, and contains a feed roll 101, a support roll 102, a wind-up roll 103, and a sputtering target 104.

A long first optical layer 4 is sent out to the support roll 102 in the state that the first optical layer 4 is in contact with the feed roll 101, and is subjected to sputtering using the sputtering target 104 in the state that the first optical layer 4 is in contact with the support roll 102 to thereby form a high refractive index layer on the convex shapes (structures) of the first optical layer 4. The first optical layer 4 to which the high refractive index layer has been formed is transported to the wind-up roll 103 via the support roll 102, and then wound up.

Moreover, a metal layer and a high refractive index layer are alternately laminated in the above-described manners to thereby form a reflective layer 3 on the first optical layer 4.

Subsequently, an optical member 1 is produced using the production device illustrated in FIG. 13 in the following manner.

First, the structure of the production device is described. The production device contains a feed roll 51, a feed roll 52, a wind-up roll 53, laminate rolls 54 and 55, guide rolls 56 to 60, a coating device 61, and an irradiation device 62.

Around the feed roll 51 and the feed roll 52, a strip of a base 5a and a strip of a first optical layer with a reflective layer 9 are respectively wound up in the form of rolls. The feed rolls 51 and 52 are disposed in a manner that the base 5a and the first optical layer with a reflective layer 9 can be continuously sent out by the guide rolls 56 and 57. In FIG. 13, the arrow indicates a direction to which the base 5a and the first optical layer with a reflective layer 9 are transported. The first optical layer with a reflective layer 9 is a first optical layer, in which a reflective layer is formed on convex shapes (structures) of the first optical layer.

The wind-up roll 53 is disposed in a manner that the wind-up roll 53 can wind up a strip of the optical member 1 produced by this production device. The laminate rolls 54 and 55 are disposed in a manner that the laminate rolls 54 and 55 can nip the first optical layer with a reflective layer 9 sent from the feed roll 52 and the base 5a sent from the feed roll 51. The guide rolls 56 to 60 are disposed in a transporting path within the production device in a manner that a strip of the first optical layer with a reflective layer 9, a strip of the base 5a, and a strip of the optical member 1 can be transported. Materials of the laminate rolls 54 and 55, and the guide rolls 56 to 60 are not particularly limited, metals, such as stainless steel, rubbers, or silicones are appropriately selected as the materials depending on the desired properties of the rolls.

As the coating device 61, for example, a device including a coating unit, such as coater, can be used. As the coater, for example, a coater, such as a gravure coater, a wire bar coater, and a die coater, can be appropriately used considering physical properties of a resin composition to coat. Examples of the irradiation device 62 includes irradiation devices applying active energy rays, such as electron beams, ultraviolet rays, visible rays, and gamma rays.

Subsequently, a production method of an optical member using the above-described production device is described.

First, a base 5a is sent out from the feed roll 51. The base 5a sent out passes through below the coating device 61 via the guide roll 56. Next, an active energy ray-curable resin is applied on the base 5a passing through below the coating device 61, by means of the coating device 61. Next, the base 5a, on which the active energy ray-curable resin has been applied, is transported towards the laminate roll. Meanwhile, a first optical layer with a reflective layer 9 is sent out from the feed roll 52, and is transported towards the laminate rolls 54 and 55 via the guide roll 57.

Next, the transported base 5a and first optical layer with a reflective layer 9 are nipped together with the laminate rolls 54 and 55 not to include air bubbles between the base 5a and the first optical layer with a reflective layer 9, to laminate the first optical layer with a reflective layer 9 on the base 5a. Next, the base 5a, on which the first optical layer with a reflective layer 9 has been laminated, is transported along the peripheral surface of the laminate roll 55, and at the same time, active energy rays are applied on the active energy ray-curable resin from the side of the base 5a by means of the irradiation device 62 to cure the active energy ray-curable resin. As a result, the base 5a and the first optical layer with a reflective layer 9 are bonded together with a resin layer (referred to as a resin layer 5b hereinafter) that is a cured product of the active energy ray-curable resin to thereby produce a target optical member 1. Next, a strip of the produced optical member 1 is transported to the wind-up roll 53 via the guide rolls 58, 59, and 60, and the optical member 1 is wound up with the wind-up roll 53.

The base and the resin layer mentioned in the production method of an optical member are specifically described below.

<<Base>>

A shape of the base 4a is not particularly limited and may be appropriately selected depending on the intended purpose. Examples of the shape include a film shape, a sheet shape, a plate shape, and a block shape. As a material of the base 4a, a conventional polymer material can be used. The conventional polymer material is not particularly limited and may be appropriately selected depending on the intended purpose. Examples of the polymer material include triacetyl cellulose (TAC), polyester (TPEE), polyethylene terephthalate (PET), polyimide (PI), polyamide (PA), aramid, polyethylene (PE), polyacrylate, polyether sulfone, polysulfone, polypropylene (PP), diacetyl cellulose, polyvinyl chloride, acrylic resins (PMMA), polycarbonate (PC), epoxy resins, urea resins, urethane resins, and melamine resins. The average thickness of the base 4a and the average thickness of the base 5a are not particularly limited and may be appropriately selected depending on the intended purpose. The average thicknesses are each preferably from 38 μm to 100 μm in view of productivity. The base 4a or the base 5a preferably has transparency to active energy rays. As a result, an active energy ray-curable resin can be cured, when active energy rays are applied to the active energy ray-curable resin present between the base 4a or the base 5a, and the reflective layer 3 from the side of the base 4a or the base 5a.

<<Resin Layer>>

For example, the resin layer 4b and the resin layer 5b have transparency. For example, the resin layer 4b is obtained by curing a resin composition between the base 4a and the reflective layer 3. For example, the resin layer 5b is obtained by curing a resin composition between the base 5a and the reflective layer 3. The resin composition is not particularly limited and may be appropriately selected depending on the intended purpose. In view of easiness of production, the resin composition is preferably an active energy ray-curable resin that can be cured by light or electron beams, or a heat-curable resin that can be cured by heat. The active energy ray-curable resin is not particularly limited and may be appropriately selected depending on the intended purpose, but the active energy ray-curable resin is preferably a photosensitive resin composition that can be cured by light, and more preferably a ultraviolet ray-curable resin composition that can be cured by ultraviolet rays.

The resin composition preferably further contains a phosphoric acid-containing compound, a succinic acid-containing compound, and a butyrolactone-containing compound for the purpose of improving adhesion between the resin layer 4b or the resin layer 5b and the reflective layer 3. The phosphoric acid-containing compound is not particularly limited and may be appropriately selected depending on the intended purpose, but the phosphoric acid-containing compound is preferably phosphoric acid-containing (meth)acrylate, and more preferably a (meth)acryl monomer or oligomer containing phosphoric acid in a functional group. The succinic acid-containing compound is not particularly limited and may be appropriately selected depending on the intended purpose, but the succinic acid-containing compound is preferably succinic acid-containing (meth)acrylate, and more preferably a (meth)acryl monomer or oligomer having succinic acid in a functional group. The butyrolactone-containing compound is not particularly limited and may be appropriately selected depending on the intended purpose, but the butyrolactone-containing compound is butyrolactone-containing (meth)acrylate, preferably a (meth)acryl monomer having butyrolactone in a functional group. At least one of the resin layer 4b and the resin layer 5b contains a functional group having high polarity, and an amount of the functional group in the resin layer 4b is preferably different from an amount of the functional group in the resin layer 5b. Both the resin layer 4b and the resin layer 5b contains a phosphoric acid-containing compound, and an amount of the phosphoric acid-containing compound in the resin layer 4b is preferably different from an amount of the phosphoric acid-containing compound in the resin layer 5b. The amount of the phosphoric acid is preferably different twice or more, more preferably 5 times or more, and particularly preferably 10 times or more between the resin layer 4b and the resin layer 5b.

In the case where at least one of the resin layer 4b and the resin layer 5b contains a phosphoric acid-containing compound, the reflective layer 3 preferably contains an oxide, nitride, or oxynitride at a surface being in contact with the resin layer 4b or resin layer 5b containing the phosphoric acid-containing compound. The reflective layer 3 particularly preferably has a thin film containing oxide of zinc at a surface being in contact with the resin layer 4b or resin layer 5b containing the phosphoric acid-containing compound.

Ingredients of the ultraviolet ray-curable resin composition are not particularly limited and may be appropriately selected depending on the intended purpose. Examples of the ingredients include (meth)acrylate and a photopolymerization initiator. Moreover, the ultraviolet ray-curable resin composition may optionally further contain a photostabilizer, a flame retardant, a leveling agent, and an antioxidant.

As the (meth)acrylate, a monomer and/or oligomer having 2 or more (meth)acryloyl groups is preferably used. The monomer and/or oligomer is not particularly limited and may be appropriately selected depending on the intended purpose. Examples of the monomer and/or oligomer include urethane (meth)acrylate, epoxy (meth)acrylate, polyester (meth)acrylate, polyol (meth)acrylate, polyether (meth)acrylate, and melamine (meth)acrylate. In the present specification, the (meth)acryloyl group means either an acryloyl group or a methacryloyl group. In the present specification, the oligomer means a molecule having a molecular weight of 500 or greater but 60,000 or smaller.

The photopolymerization initiator is not particularly limited and may be appropriately selected depending on the intended purpose. Examples of the photopolymerization initiator include benzophenone derivatives, acetophenone derivatives, and anthraquinone derivatives. The above-listed compounds may be used alone or in combination. A blending amount of the polymerization initiator is not particularly limited and may be appropriately selected depending on the intended purpose, but the blending amount is preferably 0.1% by mass or greater but 10% by mass or less in the solids. When the blending amount is less than 0.1% by mass, light curability is low, and it is not substantially suitable for industrial productions. When the blending amount is greater than 10% by mass, on the other hand, odor tends to be remained on a coating film in the case where an irradiation dose is small. The solids mean all the solids constituting the hard coating layer 12 after curing. Specifically, for example, the solids are acrylate and a photopolymerization initiator.

The resin used for the resin layer 4b is preferably a resin that does not deform at a process temperature for forming the reflective layer 3, and does not cause cracks. When the glass transition temperature of the resin is low, a resulting optical member may be deformed at a high temperature after the installation, or a shape of the resin is changed during formation of the reflective layer 3. Therefore, the resin having low glass transition temperature is not preferable. The resin having high glass transition temperature is not preferable because cracks may be formed, or the resin may be peeled from an interface. Specifically, the glass transition temperature is preferably 60° C. or higher but 150° C. or lower, and more preferably 80° C. or higher but 130° C. or lower.

The resin is not particularly limited and may be appropriately selected depending on the intended purpose. The resin is preferably a resin that can transfer a structure upon application of energy rays or heat, and is more preferably a vinyl-based resin, an epoxy-based resin, or a thermoplastic resin.

An oligomer may be added to the resin for minimizing cure shrinkage. The resin may contain polyisocyanate as a curing agent. Moreover, hydroxyl group-containing vinyl-based monomers, carboxyl group-containing vinyl-based monomers, phosphoric acid group-containing vinyl-based monomers, polyhydric alcohols, carboxylic acid, coupling agents (e.g., silane, aluminium, and titanium), or various chelating agents may be added in view of adhesion with abase.

The vinyl-based resin is not particularly limited and may be appropriately selected depending on the intended purpose, but the vinyl-based resin is preferably a (meth)acryl-based resin. As the (meth)acryl-based resin, a hydroxyl group-containing vinyl-based monomer is suitably listed. Specific examples of the (meth)acryl-based resin include various unsaturated α,β-ethylene carboxylic acid hydroxyalkylesters, such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, 3-chloro-2-hydroxypropyl (meth)acrylate, di-2-hydroxyethylfumarate, mono-2-hydroxyethyl-monobutyl fumarate, polyethylene glycol mono(meth)acrylate, polypropylene glycol mono(meth)acrylate, adducts of any of the above-listed compounds and ε-caprolactone, and “Placcel FM or FA monomer” [product name of caprolactone-added monomer, available from DAICEL CORPORATION].

The carboxyl group-containing vinyl-based monomer is not particularly limited and may be appropriately selected depending on the intended purpose. Examples of the carboxyl group-containing vinyl-based monomer include: various unsaturated mono- or di-carboxylic acid, such as (meth)acrylic acid, crotonic acid, maleic acid, fumaric acid, itaconic acid, and citraconic acid; dicarboxylic acid monoesters, such as monoethyl fumarate, and monobutyl maleate; the above-listed hydroxyl group-containing (meth)acrylates; and adducts with anhydrides of various polycarboxylic acid, such as succinic acid, maleic acid, phthalic acid, hexahydrophthalic acid, tetrahydrophthalic acid, benzene tricarboxylic acid, benzene tetracarboxylic acid, “HIMIC ACID,” and tetrachlorophthalic acid.

The phosphoric acid group-containing vinyl-based monomer is not particularly limited and may be appropriately selected depending on the intended purpose. Examples of the phosphoric acid group-containing vinyl-based monomer include dialkyl [(meth)acryloyloxyalkyl]phosphates, (meth)acryloyloxyalkyl acid phosphates, dialkyl[(meth)oxyalkyl]phosphites, and (meth)acryloyloxyalkyl acid phosphites.

As the polyhydric alcohols, for example, one or two or more of various polyhydric alcohols, such as ethylene glycol, propylene glycol, glycerin, trimethylol ethane, trimethylol propane, neopentyl glycol, 1,6-hexanediol, 1,2,6-hexanetriol, pentaerythritol, and sorbitol, can be used. Although they are not alcohols, various fatty acid glycidyl esters, such as “Curdura E” [product name of fatty acid glycidyl ester, available from Shell, Netherland] can be used instead of alcohols.

The carboxylic acid is not particularly limited and may be appropriately selected depending on the intended purpose. Examples of the carboxylic acid include various carboxylic acids, such as benzoic acid, p-tert-butyl benzoate, phthalic acid (anhydride), hexahydrophthalic acid (anhydride), tetrahydrophthalic acid (anhydride), tetrachlorophthalic acid (anhydride), hexachlorophthalic acid (anhydride), tetrabromophthalic acid (anhydride), trimellitic acid, “HIMIC ACID” [a product of Hitachi Chemical Co., Ltd.; “HIMIC ACID” is the registered trademark of Hitachi Chemical CO., Ltd.], succinic acid (anhydride), maleic acid (anhydride), fumaric acid, itaconic acid (anhydride), adipic acid, sebacic acid, and oxalic acid. The above-listed monomers may be used alone, or in combination as a copolymer.

Examples of the copolymerizable monomer include: styrene-based monomers, such as styrene, vinyl toluene, p-methyl styrene, ethyl styrene, propyl styrene, isopropyl styrene, and p-tert-butyl styrene; alkyl (meth)acrylates, such as methyl (meth)acrylate, ethyl (meth)acrylate, propyl (meth)acrylate, iso (i)-propyl (meth)acrylate, n-butyl (meth)acrylate, butyl (meth)acrylate, tert-butyl (meth)acrylate, sec-butyl (meth)acrylate, octyl (meth)acrylate, 2-ethylhexyl (meth)acrylate, lauryl (meth)acrylate, “Acryester SL” [product name of a C12-/C13 methacrylates mixture, available from MITSUBISHI RAYON CO., LTD.], and stearyl (meth)acrylate; (meth)acrylates having no functional group in side chains, such as cyclohexyl (meth)acrylate, 4-tert-butylcyclohexyl (meth)acrylate, isobornyl (meth)acrylate, adamantyl (meth)acrylate, and benzyl (meth)acrylate; bifunctional vinyl-based monomers, such as ethylene-di(meth)acrylate; various alkoxyalkyl (meth)acrylates, such as methoxyethyl (meth)acrylate, ethoxyethyl (meth)acrylate, and methoxybutyl (meth)acrylate; diesters of various dicarboxylic acids represented by maleic acid, fumaric acid, or itaconic acid, and monovalent alcohols, such as dimethyl maleate, diethyl maleate, diethyl fumarate, di(n-butyl) fumarate, di(i-butyl) fumarate, and dibutyl itaconate; various vinyl esters, such as vinyl acetate, vinyl benzoate, “VeoVa” [product name of vinyl ester of branched aliphatic monocarboxylic acid, available from Shell, Netherland], and (meth)acrylonitrile; N,N-alkylaminoalkyl (meth)acrylates, such as N-dimethylaminoethyl (meth)acrylate, and N,N-diethylaminoethyl (meth)acrylate; and nitrogen-containing vinyl-based monomers, such as amide bond-containing vinyl-based monomers (e.g., (meth)acryl amide, butyl ether of N-methylol (meth)acryl amide, and dimethylaminopropyl acryl amide.

An amount of the above-listed monomers can be appropriately adjusted depending on the properties of the high refractive index layer and the metal layer.

The base 4a or the base 5a preferably has the lower moisture vapor transmission rate than the resin layer 4b or the resin layer 5b. In the case where the resin layer 4b is formed with the active energy ray-curable resin, such as urethane acrylate, for example, the base 4a is preferably formed with a resin that has the lower moisture vapor transmission rate than the resin layer 4b, and has transmittance to active energy rays, such as polyethylene terephthalate (PET). Since the bases for use are as described above, diffusion of moisture from the incident surface S1 or the light-emitting surface S2 to the reflective layer 3 can be reduced, and deterioration of metal contained in the reflective layer 3 can be prevented. Therefore, durability of the optical member 1 can be improved. A moisture vapor transmission rate of 75 μm-thick PET is about 10 g/m²/day (40° C., 90% RH).

First to eleventh embodiments of the present invention are described with reference to the drawings hereinafter.

### First Embodiment

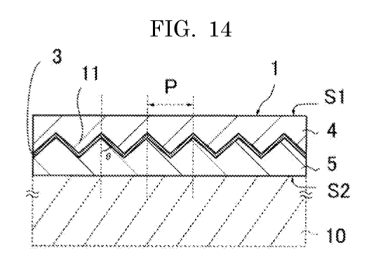

FIG. 14 is a cross-sectional view illustrating one structural example of the optical member according to the first embodiment of the present invention. As illustrated in FIG. 14, the optical member 1 includes an optical layer, and a reflective layer formed in an inner area of the optical layer. The optical member 1 has an incident surface S1 from which light, such as sunlight, enters, and a light-emitting surface S2 from which light passed through the first optical layer 4 is emitted out of the light entered from the incident surface S1.

FIG. 14 illustrates the example where the second optical layer 4 contains a pressure sensitive adhesive as a main component, and the optical member is bonded to a window material, etc. with the second optical layer 4. In the case where the optical member has the above-described structure, a difference in the refractive index between the pressure sensitive adhesive and the first optical layer is preferably within the above-mentioned range.

The first optical layer 5 and the second optical layer 4 preferably have the same optical properties, such as a refractive index. More specifically, the first optical layer 5 and the second optical layer 4 are composed of the same material having transparency in the visible region. The refractive indexes of the first optical layer 5 and the second optical layer 4 can be made identical by forming the first optical layer 5 and the second optical layer 4 using the same material, and therefore transparency of the optical member with visible light can be improved. However, attentions should be paid because a refractive index of a final film may be different depending on curing conditions in a film forming process, even though the formation of the film is started with the same material. When the first optical layer 5 and the second optical layer 4 are formed using mutually different materials, on the other hand, refractive indexes of the first optical layer and the second optical layer are different. Therefore, light is refracted with the reflective layer as a boundary, and a transmission image tends to be blurred. Especially when an object close to a point light source, such as an electric light, present far away is observed, there is a problem that a diffraction pattern is significantly observed.

The first optical layer 5 and the second optical layer 4 preferably have transparency in the visible region. In the present specification, the transparency means that absorption of light is small, and that scattering of light is small. The transparency typically denotes only the former, but the transparency preferably denotes the both in the present invention. Currently used retroreflectors, such as road signs and night-shift work clothes, aim to visualize displayed reflected light, and therefore the reflected light can be visualized as long as the retroreflectors are in contact with the underlying reflectors, even though the retroreflectors have, for example, scattering. This is the same principle to, for example, that an image can be visualized even when antiglare treatment is performed on a front surface of an image display device for the purpose of providing anti-glare properties. However, the optical member of the present invention is characterized in that the optical member passes through light other than light having a certain wavelength range that causes directional reflection, the optical member is adhered to a transparent body that mainly transmits the transmissive wavelengths to observe the transmitted light. Therefore, it is necessary that there is no scattering of light. However, scattering properties can be intentionally applied only to the second optical layer depending on the intended use.

The optical member is preferably used by bonding to a rigid body, such as a window material, having transparency to mainly light, which is other than light having a certain wavelength range, transmitted via a pressure sensitive adhesive. Examples of the window material include window materials for building, such as skyscrapers and houses, and window materials for vehicles. In the case where the optical member is applied for the window material for buildings, the optical member is particularly preferably applied for a window material arranged towards any of the directions between east and west via south (e.g., south east to south west). Since the window material is applied at the aforementioned position, heat rays can be more effectively reflected. The optical member can be used not only on a single-layer glass window, but also on special glass, such as multi-layer glass. Moreover, the window material is not limited to a material formed of glass, and a material formed of a polymer material having transparency may be used as the window material. The first optical layer and the second optical layer preferably have transparency to light in the visible region. Since the first optical layer and the second optical layer have the above-described transparency, visible light is transmitted, and lighting can be secured from sunlight in the case where the optical member is bonded to the window material, such as a glass window. Moreover, a surface to which the optical member is bonded is not only an outer surface of glass but also an inner surface of glass. In the case where the optical member is bonded to the inner surface of the glass, the optical member needs to be bonded in the manner that the front and back of the convex and concave of structures and the in-plane direction are aligned to make the directional reflection direction the predetermined direction.

The optical member preferably has flexibility considering that the optical member can be easily bonded to a window material. A shape of the optical member is not particularly limited and may be appropriately selected depending on the intended purpose. Examples of the shape include a film shape, a sheet shape, a plate shape, and a block shape, but the shape is not particularly limited to the above-listed examples.

Moreover, the optical member can be used in combination with other heat ray-cut films. For example, a light-absorbing film can be disposed at an interface between the air and the optical layer. Moreover, the optical member can be used in combination with a hard coating layer, a UV-cut layer, or a surface antireflective layer. In the case where these functional layers are used in combination, these functional layers are preferably disposed at an interface between the optical member and the air. The UV-cut layer however needs to be arranged closer to the side of sun than the optical member. In the case where the optical member is used as a member for bonding to an inner surface of a glass window for outdoor or indoor use, particularly, the UV-cut layer is desirably disposed between the glass window surface and the optical member. In this case, an ultraviolet ray-absorbing agent may be kneaded into a pressure sensitive adhesive layer between the surface of the glass window and the optical member.

Moreover, color may be applied to the optical member depending on the intended use of the optical member to give a design to the optical member. In the case where a design is provided as described, the optical member preferably has a structure where the optical layer absorbs only light having a certain wavelength range as long as transparency of the optical member is not impaired.

### Second Embodiment

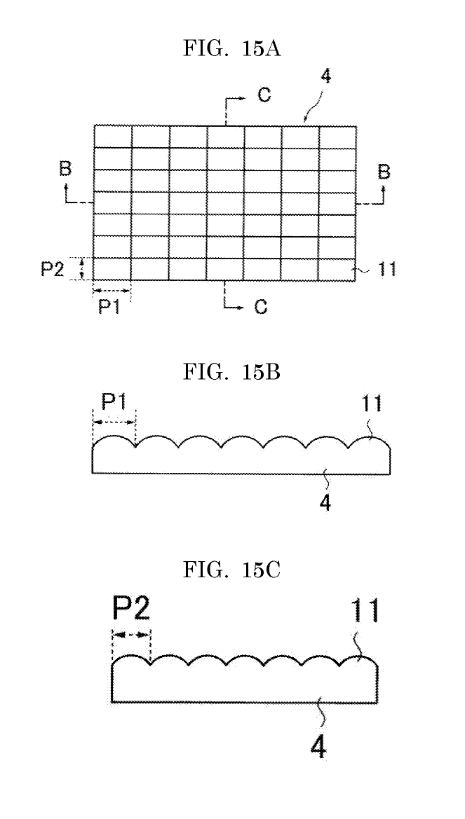

FIGS. 15 to 17 are cross-sectional views illustrating structural examples of structures of the optical member according to the second embodiment of the present invention. The second embodiment is different from the first embodiment in that the structures are two-dimensionally arranged on the main surface of the first optical layer 4.

On the main surface of the first optical layer 4, the structures 11 are two-dimensionally arranged. This arrangement is preferably an arrangement of the most densely packed state. For example, on a main surface of the first optical layer 4, a densely-packed array, such as a square densely-packed array, a delta densely-packed array, and a hexagon densely-packed array, are formed by two-dimensionally arrange the structures 11 in the most densely packed state. The square densely-packed array is an array obtained by arranging the structures 11 each having a square bottom surface in the square packed form. The delta densely-packed array is an array obtained by arranging the structures 11 each having a triangle bottom surface in the hexagonally packed form. The hexagon densely-packed array is an array obtained by arranging the structures 11 each having a hexagonal bottom surface in the hexagonally packed form.

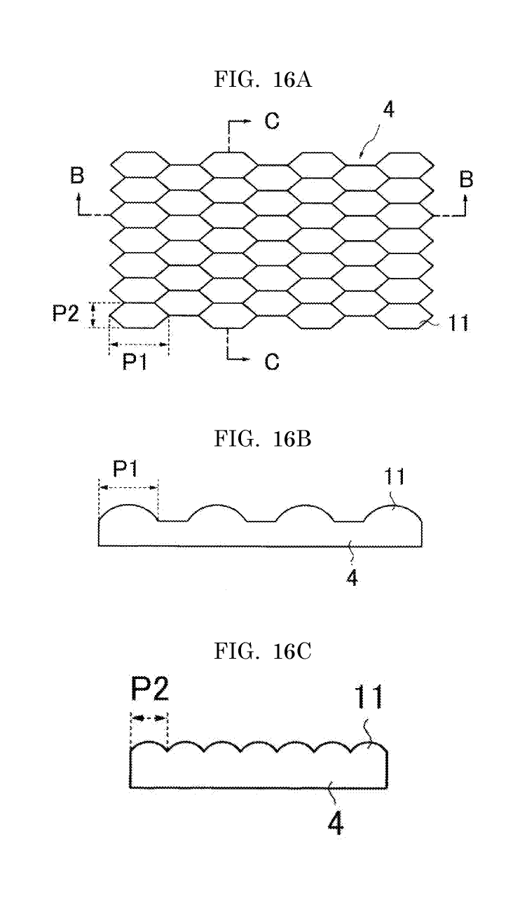

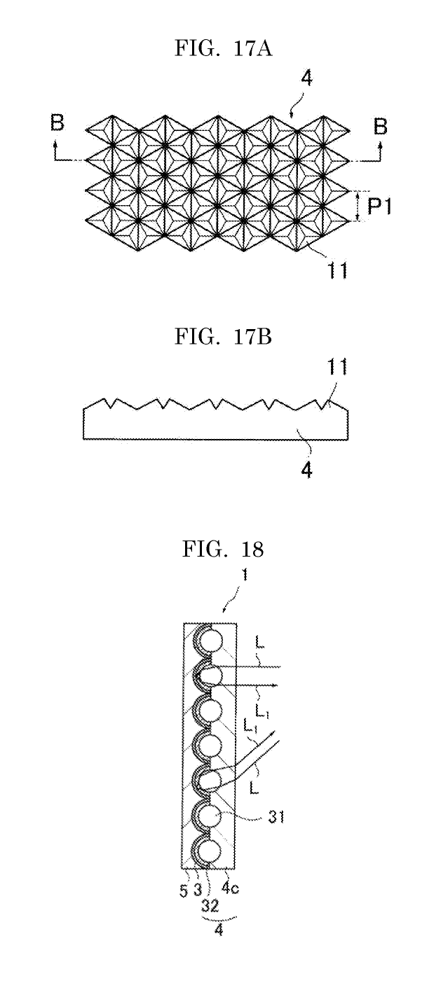

For example, the structure 11 is a convex in the shape of a corner cube, a hemisphere, a semi-ellipsoid, a prism, a free surface, a polygon, a cone, a pyramid, a circular truncated cone, or a paraboloid. Examples of a shape of the bottom surface of the structure 11 include a circle, an ellipse, and polygons, such as a triangle, a square, a hexagon, and an octagon. Note that, FIG. 15 illustrates an example of a square densely-packed array, in which the structures 11 each having a square bottom surface are two-dimensionally arranged in the most densely packed state. Moreover, FIG. 16 illustrates an example of a delta densely-packed array, in which the structures each having a hexagonal bottom surface are two-dimensionally arranged in the most densely packed state. Furthermore, FIG. 17 illustrates an example of a hexagon densely-packed array, in which the structures 11 each having a triangular bottom surface are two-dimensionally arranged in the most densely packed state. The pitch P1 or P2 of the structures 11 is preferably appropriately selected depending on the desired optical properties. In the case where a main axis of the structure 11 is inclined relative to the perpendicular line perpendicular to the incident surface of the optical member, the main axis of the structure 11 is preferably inclined along at least one of the alignment directions within the two-dimensional alignment of the structures 11. In the case where the optical member is bonded to a window material arranged perpendicular to the ground, the main axis of the structure 11 is preferably inclined to the bottom side (the ground side) of the window material with the perpendicular line l₁ being a standard.

### Third Embodiment

FIG. 18 is a cross-sectional view illustrating one structural example of the optical member according to the third embodiment of the present invention. As illustrated in FIG. 18, the third embodiment is different from the first embodiment in that the optical member has beads 31 instead of the structures 11.

The beads 31 are embedded in a main surface of the base 4c in a manner that parts of the beads 31 are projected from the main surface, and the first optical layer 4 is formed with the base 4c and the beads 31.

A focal layer 32, a reflective layer 3, and a second optical layer 5 are sequentially laminated on the main surface of the first optical layer 4. For example, the beads 31 have spherical shapes. The beads 31 preferably have transparency. For example, the beads 31 have an inorganic material, such as glass, or an organic material, such as a polymer resin, as a main component.

### Fourth Embodiment

FIG. 19 is a cross-sectional view illustrating one structural example of the optical member according to the fourth embodiment of the present invention. The fourth embodiment is different from the first embodiment in that a plurality of reflective layers 3 inclined to the light incident surface are disposed between the first optical layer 4 and the second optical layer 5, and these reflective layers 3 are arranged parallel to each other.

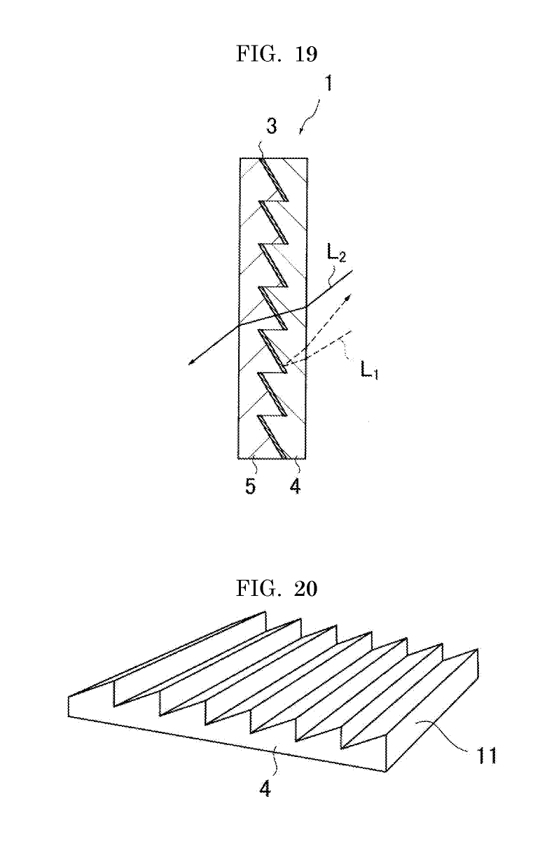

FIG. 20 is a perspective view illustrating one structural example of structures of the optical member according to the fourth embodiment of the present invention. Each of the structures 11 is a convex in the shape of a triangular prism extending one direction, and these pillar-shaped structures 11 are one-dimensionally aligned along one direction. For example, the cross-section vertical to the extending direction of the structure 11 preferably has a right-angled triangle shape. A reflective layer is formed by a thin film formation having directivity, such as vapor deposition and sputtering, performed on the inclined plane of the structure 11 at the side of the acute angle.

According to the fourth embodiment, a plurality of reflective layers are arranged parallel within the optical member. As a result, the number of reflections by the reflective layer can be reduced compared to a case where structures of corner cube shapes or prism shapes are formed. Accordingly, reflectance can be made high, and absorption of light by the reflective layer can be reduced.

### Fifth Embodiment

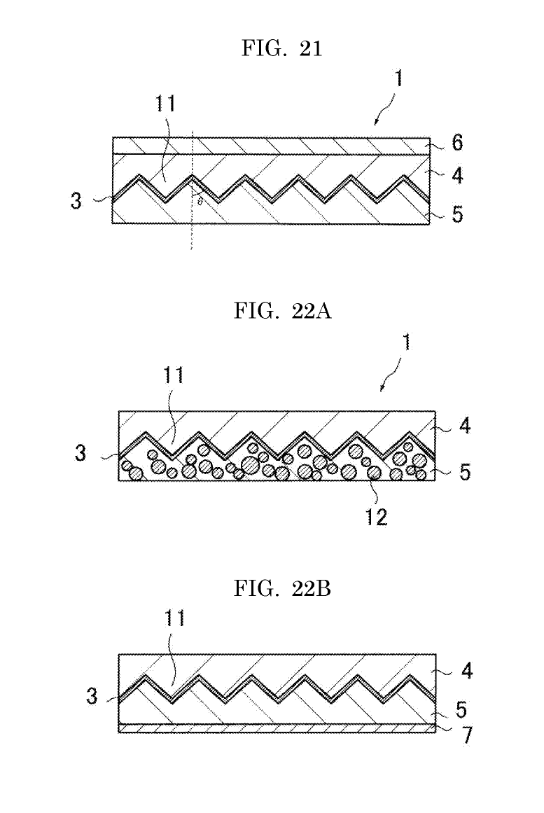

FIG. 21 is a cross-sectional view illustrating one structural example of the optical member of the fifth embodiment of the present invention. As illustrated in FIG. 21, the fifth embodiment is different from the first embodiment in that a self-cleaning effect layer 6 exhibiting a cleaning effect is further disposed on the incident surface of the optical member 1. For example, the self-cleaning effect layer 6 contains a photocatalyst. As the photocatalyst, for example, TiO₂ can be used.

As described above, the optical member has characteristics that the optical member selectively directionally reflects light having a certain wavelength range. When the optical member is used for outdoor or a room with a lot of dirt, light is scattered by the dirt attached to a surface of the optical member to lose directional reflection properties. Therefore, a surface of the optical member is preferably always optically transparent. Accordingly, the surface of the optical member is preferably excellent in water repellency or hydrophilicity, as well as exhibiting a self-cleaning effect.

According to the fifth embodiment, water repellency or hydrophilicity can be provided to an incident surface of the optical member, because the self-cleaning effect layer 6 is formed on the incident surface of the optical member. Therefore, depositions of dirt on the incident surface can be prevented, and deterioration in the directional reflection can be suppressed.

### Sixth Embodiment

The sixth embodiment is different from the first embodiment in that light other than the light having a certain wavelength range is scattered instead of directionally reflecting the light other than the light having a certain wavelength. The optical member 1 contains a light scattering body configured to scatter incident light. The light scattering body is disposed, for example, at at least one position selected from a surface of the first optical layer 4 or the second optical layer 5, inside the first optical layer 5 or the optical layer 4, and between the reflective layer 3 and the first optical layer 4 or the second optical layer 5. The light scattering body is preferably disposed at at least one position selected from between the reflective layer 3 and the second optical layer 4, inside the second optical layer 5, and a surface of the second optical layer 5. In the case where the optical member 1 is bonded to a support, such as window material, the optical member can be applied for both the indoor side and the outdoor side. In the case where the optical member 1 is bonded at the outdoor side, the light scattering body configured to scatter light other than light having a certain wavelength range is preferably disposed only between the reflective layer 3 and the support, such as a window material. This is because directional reflection properties are impaired by the presence of the light scattering body between the reflective layer 3 and the incident surface, when the optical member 1 is bonded to the support, such as a window material. In the case where the optical member 1 is bonded at the indoor side, moreover, the light scattering body is preferably disposed between the light-emitting surface, which is an opposite side to the surface of the optical member bonded to the adherend, and the reflective layer 3.

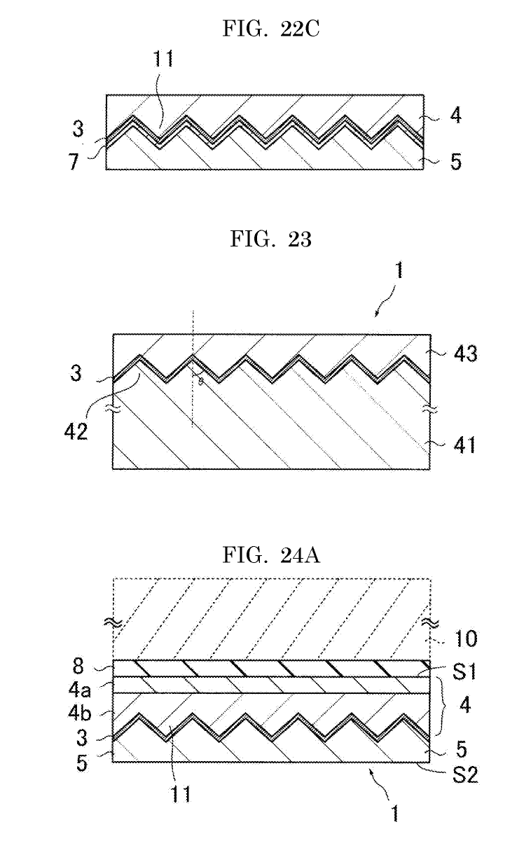

FIG. 22A is a cross-sectional view illustrating a first structural example of the optical member according to the sixth embodiment of the present invention. As illustrated in FIG. 22A, the second optical layer 5 contains a resin and particles 12. The particles 12 have a refractive index different from the refractive index of the resin, which is a main constitutional material of the second optical layer 5. As the particles 12, for example, at least one kind of organic particles or inorganic particles can be used. Moreover, hollow particles may be used as the particles 12. Examples of the particles 12 include inorganic particles, such as silica and alumina, and organic particles, such as styrene, acryl, and copolymers of styrene or acryl. The particles are particularly preferably silica particles.

FIG. 22B is a cross-sectional view illustrating a second structural example of the optical member according to the sixth embodiment of the present invention. As illustrated in FIG. 22B, the optical member 1 further includes a light diffusing layer 7 arranged on a surface of the second optical layer 5. For example, the light diffusing layer 7 contains a resin and particles. As the particles, the same particles to the particles in the first structural example can be used.

FIG. 22C is a cross-sectional view illustrating a third structural example of the optical member according to the sixth embodiment of the present invention. As illustrated in FIG. 22C, the optical member 1 further includes a light diffusing layer 7 between the reflective layer 3 and the second optical layer 5. For example, the light diffusing layer 7 contains a resin and particles. As the particles, the same particles to the particles in the first structural example can be used.

According to the sixth embodiment, light having a certain wavelength range, such as infrared rays, can be directionally reflected, and light other than the light having a certain wavelength range, such as visible light, can be scattered. Accordingly, the optical member 1 is clouded to give a design to the optical member 1.

### Seventh Embodiment

FIG. 23 is a cross-sectional view illustrating one structural example of the optical member according to the seventh embodiment of the present invention. The seventh embodiment is different from the first embodiment in that the reflective layer 3 is directly formed on a window material 41 serving as the first optical layer.

The window material 41 had structures 42 on a main surface of the window material. On the main surface where the structures 42 are formed, a reflective layer 3 and a second optical layer 43 are sequentially laminated. A shape of each structure 42 is not particularly limited and may be appropriately selected depending on the intended purpose. Examples of the shape include a shape reversing the convex and concave of the structure 11 in the first embodiment. The second optical layer 43 is configured to improve clarity of transmitted images or total light transmittance, as well as protecting the reflective layer 3. The second optical layer 43 is a layer formed by curing a resin containing, for example, a thermoplastic resin, or an active energy ray-curable resin, as a main component.

### Eighth Embodiment

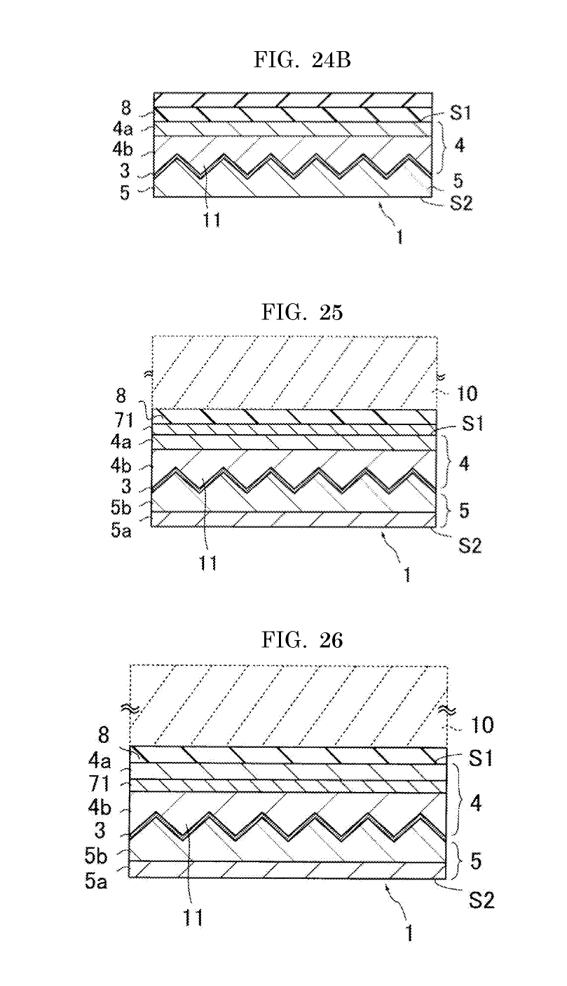

FIGS. 24A and 24B are cross-sectional views illustrating a first structural example of the optical member 1 according to the eighth embodiment of the present invention. FIGS. 25A and 25B are cross-sectional views illustrating a second structural example of the optical member 1 according to the eighth embodiment of the present invention. The eighth embodiment is different from the first embodiment in that at least one of the first optical layer 4 and the second optical layer 5 has a two-layer structure. FIGS. 24A and 24B illustrates an example where the first optical layer 4 at the side of the incident surface S1 of external light has a two-layer structure. FIGS. 25A and 25B illustrate an example where both the first optical layer 4, which is at an incident surface S1 side to the outer light, and the second optical layer 5, which is at a light-emitting surface S2 side to the outer light, have two-layer structures. As illustrated in FIGS. 24a and 24B, the two-layer structure of the first optical layer 4 contains, for example, a smooth base 4a that is disposed at a surface side, and a resin layer 4b formed between the base 4a and the reflective layer 3. As illustrated in FIGS. 25A and 25B, the two-layer structure of the second optical layer 5 contains, for example, a smooth base 5a that is disposed at a surface side, and a resin layer 5b formed between the base 5a and the reflective layer 3.

For example, the optical member 1 is bonded to an indoor side or outdoor side of the window material 10 that is an adherend via the joining layer 8. As the joining layer 8, for example, an adhesive layer containing an adhesive as a main component, or a pressure sensitive adhesive layer containing a pressure sensitive adhesive as a main component can be used. In the case where the joining layer 8 is a pressure sensitive adhesive layer, for example, the optical member 1 preferably further contains a joining layer 8 (pressure sensitive adhesive layer) formed on the incident surface S1 or the light-emitting surface S2, and a release layer 81 formed on the pressure sensitive adhesive layer, as illustrated in FIGS. 24B and 25B. Since the optical member has the above-described structure, the optical member 1 can be easily bonded to an adherend, such as a window material 10 via the joining layer 8 (pressure sensitive adhesive layer) only by peeling the release layer 81.

In view of a further improvement of adhesion between the optical member 1 and the joining layer 8, a primer layer is further formed between the optical member 1 and the joining layer 8. In similar view of a further improvement of adhesion between the optical member 1 and the joining layer 8, moreover, the incident surface S1 or light-emitting surface S2 composed of the joining layer 8 of the optical member 1 is preferably subjected to a conventional physical pretreatment. The conventional physical pretreatment is not particularly limited and may be appropriately selected depending on the intended purpose, and examples of the conventional physical pretreatment include a plasma treatment and a corona treatment.

### Ninth Embodiment

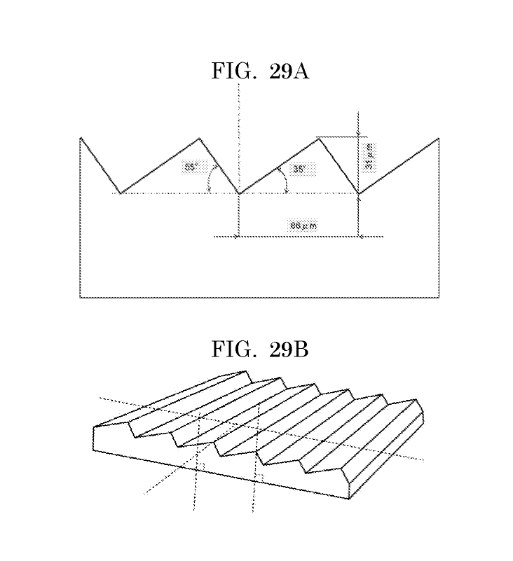

FIG. 25 is a cross-sectional view illustrating a first structural example of the optical member according to the ninth embodiment of the present invention. FIG. 26 is a cross-sectional view illustrating a second structural example of the optical member according to the ninth embodiment of the present invention. The ninth embodiment is different from the eighth embodiment in that a barrier layer 71 is further disposed on the incident surface S1 or light-emitting surface S2, to either of which an adherent, such as the window material 10, is bonded, or between the incident surface S1 or light-emitting surface S2 and the reflective layer 3. FIG. 25 illustrates an example where the optical member 1 further contains a barrier layer 71 on the incident surface S1, to which an adherent, such as the window material 10 is bonded. FIG. 28 illustrates the example where the optical member 1 further has the barrier layer 71 between the base 4a and the resin layer 4b, where the base 4a is the side to be bonded to an adherend, such as the window material 10.

As for a material of the barrier layer 71, for example, an inorganic oxide containing at least one selected from the group consisting of alumina (Al₂O₃), silica (SiOₓ), and zirconia, or a resin material containing at least one selected from the group consisting of polyvinylidene chloride (PVDC), polyvinyl fluoride resins, and ethylene-vinyl acetate copolymer partial hydrolysates can be used. As a material of the barrier layer 71, for example, a dielectric material containing at least one selected from the group consisting of SiN, ZnS—SiO₂, AlN, Al₂O₃, a composite oxide (SCZ) composed of SiO₂—Cr₂O₃—ZrO₂, a composite oxide (SIZ) composed of SiO₂—In₂O₃—ZrO₂, TiO₂, and Nb₂O₅ can be used.

In the case where the optical member 1 has the barrier layer 71 on the incident surface S1 or the light-emitting surface S2 as described above, the first optical layer 4 or the second optical layer 5, on which the barrier layer 71 is formed, preferably satisfies the following relationship. Specifically, a moisture vapor transmission rate of the base 4a or the base 5a, to which the barrier layer 71 is formed, is preferably made lower than a moisture vapor transmission rate of the resin layer 4b or the resin layer 5b. When the above-described relationship is satisfied, diffusion of moisture from the incident surface S1 or light-emitting surface S2 of the optical member 1 to the reflective layer 3 can be further reduced.

In the ninth embodiment, the optical member 1 contains the barrier layer 71 at the incident surface S1 or the light-emitting surface S2. Therefore, diffusion of moisture from the incident surface S1 or the light-emitting surface S2 into the reflective layer 3 can be reduced, and deterioration of metal contained in the reflective layer 3 can be prevented. Accordingly, durability of the optical member 1 can be improved.

### Tenth Embodiment

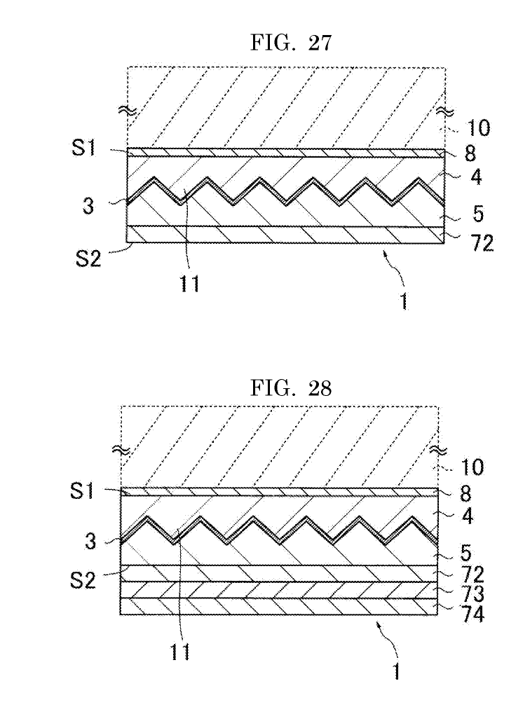

FIG. 27 is a cross-sectional view illustrating one structural example of the optical member according to the tenth embodiment of the present invention. The tenth embodiment is different from the eighth embodiment that the optical member 1 further contains a hard coating layer 72 disposed on at least one of the incident surface S1 and the light-emitting surface S2 of the optical member 1. Note that, FIG. 27 illustrates an example where the hard coating layer 72 is formed on the light-emitting surface S2 of the optical member 1.

Pencil hardness of the hard coating layer 72 is preferably 2H or higher, and more preferably 3H or higher in view of a scratch resistance of the optical member. The hard coating layer 72 is obtained by applying a resin composition onto at least one of the incident surface S1 and light-emitting surface S2 of the optical member 1, and curing the resin composition. Examples of the resin composition include resin compositions disclosed in Japanese Patent Publication Application (JP-B) Nos. 50-28092, 50-28446, and 51-24368, JP-A No. 52-112698, JP-B No. 57-2735, and JP-A No. 2001-301095. Specific examples of the resin composition include: organosilane-based heat-curable resins, such as methyltriethoxysilane, and phenyltriethoxysilane; melamine-based heat-curable resins, such as etherified methylol melamine; and polyfunctional acrylate-based ultraviolet ray-curable resin, such as polyol acrylate, polyester acrylate, urethane acrylate, and epoxy acrylate.

The resin composition preferably further contains an antifouling agent for the purpose of giving the hard coating layer 72 an antifouling performance. The antifouling agent is not particularly limited and may be appropriately selected depending on the intended purpose, but a silicone oligomer and/or fluorooligomer containing one or more (meth)acryl groups, vinyl groups, or epoxy groups is preferably used. A blended amount of the silicone oligomer and/or fluorooligomer is preferably 0.01% by mass or greater but 5% by mass or less in the solids. When the blended amount is less than 0.01% by mass, an antifouling performance tends to be insufficient. When the blended amount is greater than 5% by mass, on the other hand, hardness of a coating film tends to be low. As the antifouling agent, for example, RS-602 and RS-751-K available from DIC Corporation, CN4000 available from SARTOMER, OPTOOL DAC-HP available from DAIKIN INDUSTRIES, LTD., X-22-164E available from Shin-Etsu Chemical Co., Ltd., FM-7725 available from CHISSO CORPORATION, EBECRYL350 available from Daicel SciTech Co., Ltd., and TEGORad2700 available from Degussa AG are preferably used. A pure water contact angle of the hard coating layer 72 to which the antifouling performance is given is preferably 70° or greater and more preferably 90° or greater. The resin composition may optionally further contain additives, such as a photostabilizer, a flame retardant, and an antioxidant.

In the tenth embodiment, the hard coating layer 72 is formed on at least one of the incident surface S1 and light-emitting surface S2 of the optical member 1, scratch resistance can be provided to the optical member 1. In the case where the optical member 1 is bonded to an inner side of a window, for example, occurrences of scratches can be prevented when the surface of the optical member 1 is touched, or cleaned. In the case where the optical member 1 is bonded to an outer side of the window, moreover, occurrences of scratches can be similarly prevented.

### Eleventh Embodiments

FIG. 28 is a cross-sectional view illustrating one structural example of the optical member according to the eleventh embodiment of the present invention. The eleventh embodiment is different from the tenth embodiment in that an antifouling layer 74 is further arranged on the hard coating layer 72. Moreover, a coupling agent layer (primer layer) 73 is further disposed between the hard coating layer 72 and the antifouling layer 74 for the purpose of improving adhesion between the hard coating layer 72 and the antifouling layer 74.

In the eleventh embodiment, the optical member 1 further contains the antifouling layer 74 on the hard coating layer 72, and therefore an antifouling performance can be provided to the optical member 1.

### EXAMPLES

Examples of the present invention are explained below, but the present invention is not limited to Examples in any way.

### Example 1

A master for transferring shapes was obtained by depositing a even nickel-phosphorus plating film having no pore on an SUS roll, and ultraprecision cutting the plated surface. After washing the master for transferring shapes, shape transfer was performed using a thermosetting resin to thereby obtain a first optical layer having convex shapes.

Next, Structure A [GZO (gallium-doped zinc oxide, 35 nm)/AgNdCu (10 nm)/GZO (70 nm)/AgNdCu (10 nm)/GZO (35 nm)] was formed in this order by vacuum sputtering on the surface of the first optical layer at which the convex shapes were disposed in the manner that GZO (35 nm)/AgNdCu (10 nm)/GZO (70 nm)/AgNdCu (10 nm)/GZO (35 nm) were alternately laminated in the direction vertical to the 45°-inclined plane to thereby form a reflective layer. Note that, an alloy target having a composition of Ag/Nd/Cu=99.0 at %/0.4 at %/0.6 at % was used for forming the AgNdCu layer (metal layer) that was a silver alloy layer. A ceramic target having a composition of Ga₂O₃/ZnO=1 at %/99 at % was used for forming the GZO layer (high refractive index layer). A high refractive index layer was formed using a roll and in the state that a back surface side of a PET film that was a base was supported with the roll. As described above, the first optical layer with the reflective layer was obtained.

Next, the reflective layer was embedded in an ultraviolet ray-curable resin, to thereby obtain an optical member.

<Evaluation of Roughness of Convex Shapes>

The roughness (arithmetic average roughness Ra and maximum height roughness Rz) of the convex shapes of the first optical layer was measured by means of an atomic force microscope (AFM) (NanoScope IV, available from Veeco Instruments Inc.). Note that, the first optical layer before the reflective layer was formed in the production of the above-described optical member was used as a measurement sample. The results are presented in Table 1.

Note that, the roughness of the convex shapes can be also determined by observing a cross-section of the optical member under TEM. The values of Rz and Ra of the convex shapes calculated by the TEM cross-section observation were substantially matched with the values of Rz and Ra of the convex shapes determined with AFM.

<Measurement of Visible Light Transmittance>

A visible light transmittance of the optical member was measured by means of a UV-visible spectrometer (V-560, available from JASCO). As a result of this measurement, a function τ [λ] representing a function of a wavelength and transmittance was obtained. τ was assigned in a formula of visible ray transmittance specified in JIS A 5759 to calculate the visible light transmittance. The measuring conditions are presented below. In JIS A 5759, the transmittance was determined by bonding the sample to glass and passing light through the sample and glass. However, there is a case where a pressure sensitive adhesive and glass are discolored when a high-temperature high-humidity test is performed. Therefore, the test and the measurement were performed without bonding to glass.

Measuring mode: % T

### Response: Medium

### Bandwidth: 5.0 nm

Scanning speed: 200 nm
Starting wavelength: 380 nm
Finishing wavelength: 780 nm
Data reading gap: 1.0 nm
Vertical axis scale: automatic
Repeating number: once

The above measurement was performed on the optical member at the initial stage of the storage, and after storing at 70° C. and 90% RH for 100 hours or 500 hours.

The visible light transmittance before the storage (initial properties) is depicted in Table 1. Note that, the visible light transmittance being 15% or greater is regarded as acceptable, and the visible light transmittance being less than 15% is regarded as unacceptable.

The properties after storing were evaluated based on the following evaluation criteria. The results are presented in Table 1.

[Evaluation of Properties after Storing]

A: A variation in the visible light transmittance was less than 5% compared to the initial optical member (before the storage).
B: A variation in the visible light transmittance was 5% or greater but less than 10% compared to the initial optical member (before the storage).
C: A variation in the visible light transmittance was 10% or greater compared to the initial optical member (before the storage).

### Example 2

An optical member was produced in the same manner as in Example 1, except that the master for transferring shapes was replaced with a master for transferring shapes obtained by depositing a even nickel-phosphorus plating film having no pore on an SUS roll, followed by cutting the plated surface using a cutting tool having wear of 1 μm. Moreover, evaluations were performed in the same manner as in Example 1. The results are presented in Table 1.

### Example 3

An optical member was produced in the same manner as in Example 1, except that the master for transferring shapes was replaced with a master for transferring shapes obtained by depositing a nickel-phosphorus plating film having pores having diameters of 50 nm or smaller on an SUS roll, followed by ultraprecision cutting the plated surface. Moreover, evaluations were performed in the same manner as in Example 1. The results are presented in Table 1.

### Example 4

An optical member was produced in the same manner as in Example 1, except that the master for transferring shapes was replaced with a master for transferring shapes obtained by depositing a nickel-phosphorus plating film having pores having diameters of 100 nm or smaller on an SUS roll, followed by ultraprecision cutting the plated surface, and the reflective layer was replaced with a single-layer reflective layer composed only of an AgNdCu layer (metal layer) having the average thickness of 20 nm. Moreover, evaluations were performed in the same manner as in Example 1. The results are presented in Table 1.

### Example 5

An optical member was produced in the same manner as in Example 4, except that the average thickness of the AgNdCu layer (metal layer) was changed to 40 nm. Moreover, evaluations were performed in the same manner as in Example 1. The results are presented in Table 1.

### Comparative Example 1

An optical member was produced in the same manner as in Example 1, except that the master for transferring shapes was replaced with a master for transferring shapes obtained by depositing a nickel-phosphorus plating film having pores having diameters of 100 nm or smaller on an SUS roll, followed by ultraprecision cutting the plated surface. Moreover, evaluations were performed in the same manner as in Example 1. The results are presented in Table 1.

### Comparative Example 2

An optical member was produced in the same manner as in Example 1, except that the master for transferring shapes was replaced with a master for transferring shapes obtained by ultraprecision cutting a Cu-plated SUS roll, followed by plating the cut piece with Cr. Moreover, evaluations were performed in the same manner as in Example 1. The results are presented in Table 1.

### Comparative Example 3

An optical member was produced in the same manner as in Example 3, except that the average thickness of the reflective layer was changed to 7 nm. Moreover, evaluations were performed in the same manner as in Example 1. The results are presented in Table 1.

### Comparative Example 4

An optical member was produced in the same manner as in Example 4, except that the average thickness of the reflective layer was changed to 50 nm. Moreover, evaluations were performed in the same manner as in Example 1. The results are presented in Table 1.

TABLE 1

| | | | | | Initial | | | |
|---|---|---|---|---|---|---|---|---|
| | | | Thickness | Rz/Ag | properties | | | |
| | | | of Ag | alloy | visible light | Properties | Properties | |
| | Rz | Ra | alloy layer | layer | transmittance | after storing | after storing | |
| | (nm) | (nm) | (nm) | ratio | (%) | for 100 h | for 500 h | Judgement |
| Ex. 1 | 11 | 1.1 | 10 | 1.1 | 71 | A | A | OK |
| Ex. 2 | 20 | 1.7 | 10 | 2 | 70 | A | A | OK |
| Ex. 3 | 27 | 2.1 | 10 | 2.7 | 69 | A | A | OK |
| Ex. 4 | 43 | 3.7 | 20 | 2.2 | 45 | A | A | OK |
| Ex. 5 | 43 | 3.7 | 40 | 1.1 | 18 | A | A | OK |
| Comp. | 43 | 3.7 | 10 | 4.3 | 68 | A | B | NG |
| Ex. 1 | | | | | | | | |
| Comp. | 56 | 5.0 | 10 | 5.6 | 68 | B | C | NG |
| Ex. 2 | | | | | | | | |
| Comp. | 27 | 2.1 | 7 | 3.9 | 71 | A | B | NG |
| Ex. 3 | | | | | | | | |
| Comp. | 43 | 3.7 | 50 | 0.86 | 11 | A | A | NG |
| Ex. 4 | | | | | | | | |

It was found that the optical member of the present invention could suppress a variation in the visible light transmittance and had excellent durability when the minimum height roughness Rz (nm) of the inclined planes of the convex shapes was 3.0 times or less the average thickness (nm) of the metal layer. When the average thickness of the metal layer was greater than 40 nm, moreover, the initial visible light transmittance was low to the extent that the visible light transmittance was lower than 15%.

### INDUSTRIAL APPLICABILITY

Since the optical member of the present invention has excellent durability, the optical member is suitably used as a heat ray reflecting optical member used for a glass window.

### DESCRIPTION OF THE REFERENCE NUMERAL

1 optical member
3 reflective layer
4 first optical layer
4a base
4b resin layer
4c base
5 second optical layer
5a base
5b resin layer
5b′ resin
6 self-cleaning effect layer
7 light scattering layer
8 joining layer
9 first optical layer with reflective layer
10 window material
11 structure
12 particles
23 light source
31 beads
32 focal layer
41 window material
42 structure
43 second optical layer
51 feed roll
52 feed roll
53 wind-up roll
54 laminate roll
55 laminate roll
56 guide roll
57 guide roll
58 guide roll
59 guide roll
60 guide roll
61 coating device
62 irradiation device
71 barrier layer
72 hard coating layer
73 coupling agent layer
74 antifouling layer
81 release layer
101 feed roll
102 support roll
103 wind-up roll
104 sputtering target
401 joinery
402 optical member
403 frame material
404 light collection part
500 building
600 building
S incident light
S1 incident surface
S2 light-emitting surface
L incident light
L₁ light reflecting to the sky
L₂ light not reflecting to the sky

1. An optical member comprising:
a first optical layer having convex shapes; and
a reflective layer, which is formed on the convex shapes of the first optical layer and is configured to reflect light including at least infrared light,
wherein the reflective layer includes at least a metal layer,
wherein a maximum height roughness Rz (nm) of inclined planes of the convex shapes is 3.0 times or less an average thickness (nm) of the metal layer, and
wherein the average thickness of the metal layer is 40 nm or less.

2. The optical member according to claim 1,
wherein the convex shapes of the first optical layer are formed with a one-dimensional alignment or a two-dimensional alignment of a plurality of structures, and the structures are prism shapes, lenticular shapes, hemispherical shapes, or corner cube shapes.

3. The optical member according to claim 1,
wherein the first optical layer is formed of a thermoplastic resin, an active energy ray-curable resin, or a thermosetting resin.

4. The optical member according to claim 1,
wherein each of the convex shapes of the first optical layer is a shape including a plane inclined at 45° or greater relative to a plane of the first optical layer opposite to the plane on which the convex shapes are formed.

5. The optical member according to claim 1,
wherein a pitch of the convex shapes of the first optical layer is from 20 μm to 150 μm.

6. A window material comprising:
the optical member according to claim 1.

7. Joinery comprising:
a light collection part from which sunlight is taken in,
wherein the light collection part includes the optical member according to claim 1.

8. A production method of the optical member according to claim 1, the production method comprising:
forming the first optical layer having convex shapes using a transfer master having concave shapes; and
forming the reflective layer on the convex shapes of the first optical layer, where the reflective layer includes at least a metal layer and is configured to reflect light including at least infrared light.
